(19) United States
(12) Patent Application Publication
(10) Pub. No.: US 2026/0180566 A1
(43) Pub. Date: Jun. 25, 2026

(54) SIGNAL RECEIVING METHOD AND APPARATUS

(71) Applicant: HUAWEI TECHNOLOGIES CO., LTD., Shenzhen (CN)

(72) Inventors: Hongli He, Beijing (CN); Xueru Li, Beijing (CN)

(73) Assignee: HUAWEI TECHNOLOGIES CO., LTD., Shenzhen (CN)

(21) Appl. No.: 19/536,483

(22) Filed: Feb. 11, 2026

Related U.S. Application Data
(63) Continuation of application No. PCT/CN2024/113195, filed on Aug. 19, 2024.

(30) Foreign Application Priority Data
Sep. 8, 2023 (CN) 202311160179.2

(51) Int. Cl. H03K 5/13; H04L 5/00; H04L 27/26

(52) U.S. Cl. CPC H03K 5/13; H04L 5/0048; H04L 27/2662

(57) ABSTRACT

A signal receiving method and an apparatus. The method includes: A receiving device receives a first signal, performs down-conversion on the first signal to obtain a second signal, then determines a third signal based on the second signal, and samples the third signal to determine a target signal. The first signal includes the target signal, and comb mapping is used for the target signal. The third signal includes superposition of K delayed signals of the second signal, and delay time associated with a k^{th} delayed signal in the K delayed signals is

$$\frac{( k - 1 ) T}{K} + δ .$$

T is a time length of the first signal, k=1, 2, . . . , or K, δ is greater than or equal to 0, M is a positive integer greater than 1, and K is a positive integer greater than or equal to M.

### CROSS-REFERENCE TO RELATED APPLICATIONS

This application is a continuation of International Application No. PCT/CN2024/113195, filed on Aug. 19, 2024, which claims priorities to Chinese Patent Application No. 202311160179.2, filed on Sep. 8, 2023. The disclosures of the aforementioned applications are hereby incorporated by reference in their entireties.

### TECHNICAL FIELD

Embodiments relate to the communication field, for example, to a signal receiving method and an apparatus.

### BACKGROUND

In the future, wireless sensing may be an important part of a mobile communication system. To implement harmonious coexistence of communication and sensing and sharing of radio frequency and baseband devices in communication and sensing, an orthogonal frequency division multiplexing (OFDM) waveform may be used in the mobile communication system to implement communication and sensing.

In a wireless sensing scenario based on the OFDM waveform, a sensing device may send a signal in a comb manner or an interlace manner. For example, as shown in FIG. 1, one subcarrier in every M (for example, M=2) consecutive subcarriers may be used by the sensing device to send a sensing signal, and the other subcarriers in the M consecutive subcarriers may be used by another sensing device or communication device to send a signal.

In a signal receiving process based on the OFDM waveform, a receiver inputs a time domain signal on an entire bandwidth to an analog-to-digital converter (ADC), to convert a time domain analog signal into a time domain digital signal; then, a frequency domain digital signal is obtained through serial-to-parallel (S->P) conversion and fast Fourier transform (FFT); and then, a signal on a subcarrier on which the sensing signal is located is extracted from the frequency domain digital signal for subsequent processing.

Due to limited quantization precision of the ADC, additional quantization noise may be generated after a signal passes through the ADC. In the foregoing signal receiving process, the quantization noise of the ADC depends on a sum of powers of the sensing signal and a signal of another user. If the power of the signal of another user received by the receiver is excessively high, large quantization noise is caused, affecting receiving performance.

### SUMMARY

Embodiments provide a signal receiving method and an apparatus, to reduce a peak power of a signal input to an ADC, so as to reduce quantization noise and improve signal receiving performance.

According to a first aspect, a signal receiving method is provided. The method may be performed by a receiving device, may be performed by a component of the receiving device, for example, a processor, a chip, or a chip system of the receiving device, or may be implemented by a logical module or software that can implement all or some functions of the receiving device. The method includes: receiving a first signal, where the first signal includes a target signal, the target signal occupies one subcarrier in every M consecutive subcarriers, and M is a positive integer greater than 1; performing down-conversion on the first signal to obtain a second signal; determining a third signal based on the second signal, where the third signal includes superposition of K delayed signals of the second signal, and delay time associated with a k^{th} delayed signal in the K delayed signals is

$$\frac{( k - 1 ) T}{K} + δ ,$$

where T is a time length of the first signal, k=1, 2, . . . , or K, δ is greater than or equal to 0, and K is a positive integer greater than or equal to M; and sampling the third signal to determine the target signal.

Based on this solution, because the delay time associated with the k^{th} delayed signal is

$$\frac{( k - 1 ) T}{K} + δ ,$$

the K delayed signals of the second signal may be equivalent to periodic extension of the second signal. Performing sampling in frequency domain is equivalent to performing periodic extension on a signal in time domain, and extracting the target signal from an entire bandwidth may be understood as sampling in frequency domain. Therefore, after periodic extension and superposition are performed in time domain, it may be considered that the target signal has been extracted. In this case, a signal input to an ADC during sampling does not include a signal of another user. In other words, a peak power of the signal input to the ADC is a power of the target signal, and does not include a power of the signal of another user. In this way, the peak power of the signal input to the ADC can be reduced, so as to reduce quantization noise and improve signal receiving performance.

In a possible embodiment, the time length of the first signal is a length of one OFDM symbol. In other words, the first signal may be understood as a signal on one OFDM symbol. The length of one OFDM symbol may be a length of a part excluding a cyclic prefix (CP) part.

In a possible embodiment, a frequency of the down-conversion is related to a carrier frequency of the first signal and/or a position of the target signal. For example, the frequency of the down-conversion may be the same as a frequency of a subcarrier included (or occupied) by the target signal.

Based on the possible embodiment, after the down-conversion, a radio frequency signal (for example, the first signal) having a high frequency may be shifted to a baseband for processing. In addition, the frequency of the down-conversion is determined based on the carrier frequency of the first signal and/or the position of the target signal, and the target signal may be aligned with a baseband zero frequency after the down-conversion, to facilitate subsequent processing.

In a possible embodiment, determining the third signal based on the second signal includes: delaying the second signal K times to obtain the K delayed signals of the second signal, where the delay time associated with the k^{th} delayed signal is

$$\frac{( k - 1 ) T}{K} + δ ;$$

and superposing the K delayed signals to obtain the third signal. Based on the possible embodiment, the third signal may be obtained by directly delaying the second signal K times and superposing the delayed signals.

In a possible embodiment, determining the third signal based on the second signal includes: determining the third signal by using an X-stage circuit, wherein the X-stage circuit, an output signal of an i^{th}-stage circuit is a signal obtained by superposing an input signal of the i^{th}-stage circuit and a signal obtained by delaying the input signal of the i^{th}-stage circuit, where i=1, 2, . . . , or X, and X is a positive integer greater than 1. When i=1, the input signal of the i^{th}-stage circuit is a signal obtained by delaying the second signal by δ, or when i>1, the input signal of the i^{th}-stage circuit is an output signal of an (i−1)^{th}-stage circuit, the third signal is an output signal of an X^{th}-stage circuit, and the output signal of the X^{th}-stage circuit includes superposition of the K delayed signals of the second signal.

In a possible embodiment, K=2^{X}, and the output signal of the i^{th}-stage circuit is a signal obtained by superposing the input signal of the i^{th}-stage circuit and a signal obtained by delaying the input signal of the i^{th}-stage circuit by

$$\frac{T}{{2}^{i}} .$$

Based on the possible embodiment, because the input signal of the i^{th}-stage circuit may be delayed only once, only one delayer may be required in each stage of circuit. In other words, only a total of X delayers may be required to determine the third signal. This can reduce a quantity of delayers, to reduce costs of the receiving device.

In a possible embodiment,

$$K = {\prod }_{i = 1}^{X} {K}_{i} ,$$

and the output signal of the i^{th}-stage circuit is a signal obtained by superposing the input signal of the i^{th}-stage circuit and signals obtained by respectively delaying the input signal of the i^{th}-stage circuit by

$$\frac{T}{{\prod }_{j = 1}^{i} {K}_{j}} , \frac{2 T}{{\prod }_{j = 1}^{i} {K}_{j}} , ... , and \frac{( {K}_{i} - 1 ) T}{{\prod }_{j = 1}^{i} {K}_{j}} ,$$

where Π represents cumulative multiplication, and Kᵢ is a positive integer.

In a possible embodiment, K=M, and sampling the third signal includes: sampling the third signal within a time range of

$$[ \frac{M - 1}{M} T + δ , T + δ ] ,$$

where a reference point of the time range is start time of the first signal.

Based on the possible embodiment, a length of a time domain range may be T/M. In other words, within a time length T of one OFDM symbol, duration in which an ADC used for sampling is turned on or operating is only required to be T/M. In comparison with a case in which the ADC is turned on within the time length T, this case can reduce sampling power consumption of the ADC, to reduce power consumption of the receiving device. In addition, based on the possible embodiment, if a sampling rate for sampling the third signal within the time range is NΔf_{C}, when the length of the time domain range is T/M, the target signal includes N/M sampling points in time domain. Subsequently, only

$$\frac{N}{M} - point$$

discrete Fourier transform (DFT) may be performed to obtain a frequency domain signal corresponding to the target signal. In comparison with a solution in which at least N-point DFT is performed on a signal on an entire OFDM symbol, this solution can reduce a quantity of DFT points, and reduce a capability requirement and costs for a DFT module.

In a possible embodiment, K=M, and sampling the third signal includes: delaying the third signal A times to obtain A delayed signals of the third signal, where A is a positive integer, delay time associated with an a^{th} delayed signal is

$$\frac{( a - 1 ) T}{M} + {δ}_{a} ,$$

δₐ is greater than or equal to 0, and a=1, 2, . . . , or A; and sampling the a^{th} delayed signal of the third signal within a time range of

$$[ \frac{M + a - 2}{M} T + δ + {\sum }_{j = 1}^{a} {δ}_{j} , \frac{M + a - 1}{M} T + δ + {\sum }_{j = 1}^{a} {δ}_{j} ] ,$$

where a reference point of the time range is start time of the first signal. For example, A is a positive integer less than or equal to M. In a special case, A=M.

In a possible embodiment, a sampling frequency used for sampling the a^{th} delayed signal of the third signal is greater than or equal to NΔf_{C}/A, where N is greater than or equal to a quantity of subcarriers included in a bandwidth of the first signal, N is a positive integer, and Δf_{C} is a bandwidth of the subcarrier. Alternatively, a sampling frequency of the a^{th} delayed signal of the third signal is B/A, and B is a bandwidth of the first signal.

Based on the possible embodiment, the receiving device delays the third signal A times, and samples the delayed signal of the third signal within the foregoing time domain range. This is equivalent to making an additional copy of a signal of the target signal in time domain, and sampling a plurality of copied time domain signals. It may be considered that a time length of total sampling samples is increased. When a total quantity of sampling points remains unchanged, each sampling sample may be sampled by using a low sampling frequency, so that the sampling frequency can be reduced, and a performance requirement and costs for an ADC are also reduced.

In a possible embodiment, sampling positions of any two delayed signals in the A delayed signals of the third signal are different.

Based on the possible embodiment, the different sampling positions of the any two delayed signals can ensure that sampling points of the any two delayed signals are different, and corresponding sampling results are not repeated, to ensure sufficient sampling and improve sampling performance.

In a possible embodiment, K=M−1+C, and C is a positive integer. For example, C is a positive integer less than or equal to M. In a special case, C=M.

In a possible embodiment, sampling the third signal includes: performing C segments of sampling on the third signal. A c^{th} segment of sampling corresponds to a signal of the third signal within a time range c, c=1, 2, . . . , or C, and the time range c is

$$[ \frac{M + c - 2}{M} T + δ , \frac{M + c - 1}{M} T + δ ] .$$

A reference point of the time range c is start time of the first signal.

In a possible embodiment, a sampling frequency used for performing C segments of sampling on the third signal is greater than or equal to NΔf_{C}/C, where N is greater than or equal to a quantity of subcarriers included in a bandwidth of the first signal, N is a positive integer, and Δf_{C} is a bandwidth of the subcarrier.

Based on the foregoing two possible embodiments, the sampling frequency and a quantity of DFT points can also be reduced, so that capability requirements and costs for an ADC and a DFT module are reduced.

In a possible embodiment, sampling positions in any two segments of sampling in the C segments of sampling of the third signal are different.

In a possible embodiment, sampling the third signal to determine the target signal includes: sampling the third signal to obtain a first time domain sequence, and performing N/M-point discrete Fourier transform DFT on the first time domain sequence to obtain a frequency domain signal corresponding to the target signal, where N is greater than or equal to the quantity of subcarriers included in the bandwidth of the first signal, and N is a positive integer.

Based on the possible embodiment, only

$$\frac{N}{M} - point DFT$$

may be performed to obtain the frequency domain signal corresponding to the target signal. In comparison with a solution in which at least N-point DFT is performed on a signal on an entire OFDM symbol, this solution can reduce a quantity of DFT points, and reduce a capability requirement and costs for a DFT module.

According to a second aspect, an apparatus is provided. The apparatus may be a communication apparatus or a sensing apparatus. The apparatus includes a first circuit. The first circuit is configured to determine a third signal based on a second signal, where the third signal includes superposition of K delayed signals of the second signal, and delay time associated with a k^{th} delayed signal in the K delayed signals is

$$\frac{( k - 1 ) T}{K} + δ ;$$

the second signal is a signal obtained by performing down-conversion on a first signal, the first signal includes a target signal, the target signal occupies one subcarrier in every M consecutive subcarriers, M is a positive integer greater than 1, T is a time length of the first signal, k=1, 2, . . . , or K, δ is greater than or equal to 0, and K is a positive integer greater than or equal to M; and the third signal is an input signal of an analog-to-digital converter. For effects brought by the second aspect, refer at least to effects brought by the first aspect. Details are not described herein again.

In a possible embodiment, the apparatus further includes at least one of the following: an antenna, a frequency mixer, the analog-to-digital converter, a DFT module, and a second circuit.

In a possible embodiment, the first circuit includes K delayers and one adder. A k^{th} delayer in the K delayers is configured to delay the second signal by

$$\frac{( k - 1 ) T}{K} + δ$$

to obtain the k^{th} delayed signal of the second signal. The adder is configured to superpose the K delayed signals of the second signal to obtain the third signal. The adder is a K-input adder.

In a possible embodiment, in a special case, when δ=0, a delay associated with a 1^{st} delayed signal in the foregoing embodiment is 0. In this case, the 1^{st} delayed signal is equivalent to the second signal. Therefore, the 1^{st} delayed signal can be obtained without using the delayer. Therefore, the first circuit may include K−1 delayers and one adder. A k^{th} delayer in the K−1 delayers is configured to delay the second signal by

$$\frac{k T}{K}$$

to obtain the k^{th} delayed signal of the second signal. The adder is configured to superpose the second signal and K−1 delayed signals of the second signal to obtain the third signal. The adder is a K-input adder. Based on the possible embodiment, one delayer may be reduced.

In a possible embodiment, the first circuit includes an X-stage circuit, and in the X-stage circuit, an output signal of an i^{th}-stage circuit is a signal obtained by superposing an input signal of the i^{th}-stage circuit and a signal obtained by delaying the input signal of the i^{th}-stage circuit, where i=1, 2, . . . , or X, and X is a positive integer greater than 1. When i=1, the input signal of the i^{th}-stage circuit is a signal obtained by delaying the second signal by δ, or when i>1, the input signal of the i^{th}-stage circuit is an output signal of an (i−1)^{th}-stage circuit, the third signal is an output signal of an X^{th}-stage circuit, and the output signal of the X^{th}-stage circuit includes superposition of the K delayed signals of the second signal.

In a possible embodiment, when K=2^{X}, the i^{th}-stage circuit includes one delayer and one adder. The delayer is configured to delay the input signal of the i^{th}-stage circuit by

$$\frac{T}{{2}^{i}} .$$

The adder is configured to superpose the input signal of the i^{th}-stage circuit and an output signal of the delayer in the i^{th}-stage circuit.

In a possible embodiment, when

$$K = {Π}_{i = 1}^{X} {K}_{i} ,$$

the i^{th}-stage circuit includes Kᵢ−1 delayers and one adder. The Kᵢ−1 delayers are respectively configured to delay the input signal of the i^{th}-stage circuit by

$$\frac{T}{{Π}_{j = 1}^{i} {K}_{j}} , \frac{2 T}{{Π}_{j = 1}^{i} {K}_{j}} , … , and \frac{( {K}_{i} - 1 ) T}{{Π}_{j = 1}^{i} {K}_{j}} .$$

The adder is configured to superpose the input signal of the i^{th}-stage circuit and output signals of the Kᵢ−1 delayers in the i^{th}-stage circuit.

In a possible embodiment, when K=M, the analog-to-digital converter is configured to sample the third signal within a time range of

$$[ \frac{M - 1}{M} T + δ , T + δ ] ,$$

where a reference point of the time range is start time of the first signal.

In a possible embodiment, when K=M, the second circuit is configured to delay the third signal A times to obtain A delayed signals of the third signal, where A is a positive integer, delay time associated with an a^{th} delayed signal is

$$\frac{( a - 1 ) T}{M} + {δ}_{a} ,$$

δₐ is greater than or equal to 0, and a=1, 2, . . . , or A. The analog-to-digital converter is configured to sample the a^{th} delayed signal of the third signal within a time range of

$$[ \frac{M + a - 2}{M} T + δ + {\sum }_{j = 1}^{a} {δ}_{j} , \frac{M + a - 1}{M} T + δ + {\sum }_{j = 1}^{a} {δ}_{j} ] ,$$

where a reference point of the time range is start time of the first signal.

In a possible embodiment, when K=M−1+B, and B is a positive integer, the analog-to-digital converter is configured to perform C segments of sampling on the third signal. A c^{th} segment of sampling corresponds to a signal of the third signal within a time range c, c=1, 2, . . . , or C, and the time range c is

$$[ \frac{M + c - 2}{M} T + δ , \frac{M + c - 1}{M} T + δ ] .$$

A reference point of the time range c is start time of the first signal.

In a possible embodiment, the DFT module is configured to perform N/M-point discrete Fourier transform DFT on a first time domain sequence to obtain a frequency domain signal corresponding to the target signal, where the first time domain sequence is a sampling result corresponding to the third signal, N is greater than or equal to a quantity of subcarriers included in a bandwidth of the first signal, and N is a positive integer.

In a possible embodiment, the antenna is configured to receive the first signal. The first signal includes the target signal, and the target signal occupies one subcarrier in every M consecutive subcarriers.

In a possible embodiment, the frequency mixer is configured to perform down-conversion on the first signal to obtain the second signal.

In a possible embodiment, the apparatus according to the second aspect is a chip or a chip system.

For effects brought by any possible embodiment of the second aspect, refer at least to effects brought by the corresponding embodiment of the first aspect. Details are not described herein again.

According to a third aspect, an apparatus is provided. The apparatus may be a communication apparatus or a sensing apparatus. The apparatus includes a unit or a module, and the unit or the module is configured to perform any method according to the first aspect. The module or the unit may be implemented by hardware or software, or implemented by hardware executing corresponding software. The hardware or the software includes one or more modules or units corresponding to functions.

In some possible embodiments, the apparatus may include a processing module and a transceiver module. The processing module may be configured to implement a processing function in any one of the foregoing aspects and the possible embodiments of the foregoing aspects. The transceiver module may include a receiving module and a sending module that are respectively configured to implement a receiving function and a sending function in any one of the foregoing aspects and the possible embodiments of the foregoing aspects.

In some possible embodiments, the transceiver module may include a transceiver circuit, a transceiver machine, a transceiver, or a communication interface.

According to a fourth aspect, an apparatus is provided. The apparatus may be a communication apparatus or a sensing apparatus. The apparatus includes a processor. The processor is configured to perform any method according to the first aspect. There may be one or more processors. The apparatus may further include a memory. The memory is configured to store computer instructions. When the processor executes the instructions, the apparatus is caused to perform any method according to the first aspect. The memory may be coupled to the processor, or may be independent of the processor. The apparatus may further include a communication interface. The communication interface is configured to communicate with a module outside the apparatus.

The apparatuses in the second aspect, the third aspect, and the fourth aspect may be the receiving device in the first aspect or an apparatus included in the receiving device, for example, a chip or a chip system. When the apparatus is a chip, a sending action/function of the apparatus may be understood as outputting information, and a receiving action/function of the apparatus may be understood as inputting information.

According to a fifth aspect, a non-transitory computer-readable storage medium is provided. The non-transitory computer-readable storage medium stores a computer program or instructions. When the computer program or the instructions are run on an apparatus, the apparatus is caused to perform any method according to the first aspect. The apparatus may be a communication apparatus or a sensing apparatus.

According to a sixth aspect, a computer program product including instructions is provided. When the computer program product runs on an apparatus, the apparatus is caused to perform any method according to the first aspect. The apparatus may be a communication apparatus or a sensing apparatus.

For effects brought by any one of the embodiments of the second aspect to the sixth aspect, refer at least to effects brought by the different embodiments of the first aspect. Details are not described herein again.

### BRIEF DESCRIPTION OF DRAWINGS

FIG. 1 is a diagram of a comb structure according to the embodiments;

FIG. 2 is a schematic flowchart of signal receiving according to the embodiments;

FIG. 3 is a diagram of a structure of a communication system according to the embodiments;

FIG. 4 is a schematic flowchart of a signal receiving method according to the embodiments;

FIG. 5 is a diagram of a comb structure or an interlace structure according to the embodiments;

FIG. 6 is a schematic flowchart of signal receiving according to the embodiments;

FIG. 7 is another schematic flowchart of signal receiving according to the embodiments;

FIG. 8 is still another schematic flowchart of signal receiving according to the embodiments;

FIG. 9 is yet another schematic flowchart of signal receiving according to the embodiments;

FIG. 10 is a diagram of positions of sampling points according to the embodiments;

FIG. 11 is a diagram of a structure of a communication apparatus according to the embodiments;

FIG. 12 is a diagram of a structure of another communication apparatus according to the embodiments;

FIG. 13 is a diagram of a structure of still another communication apparatus according to the embodiments; and

FIG. 14 is a diagram of a structure of yet another communication apparatus according to the embodiments.

### DETAILED DESCRIPTION OF EMBODIMENTS

In descriptions herein, unless otherwise specified, “/” represents an “or” relationship between associated objects. For example, A/B may represent A or B. In the embodiments, “and/or” describes only an association relationship between associated objects, and represents that three relationships may exist. For example, A and/or B may represent the following three cases: only A exists, both A and B exist, and only B exists, where A and B may be singular or plural.

In addition, in the descriptions, unless otherwise specified, “a plurality of” means two or more. “At least one of the following items (pieces)” or a similar expression thereof means any combination of these items, including a singular item (piece) or any combination of plural items (pieces). For example, at least one item (piece) of a, b, and (or) c may indicate a, b, c, a and b, a and c, b and c, or a, b, and c, where a, b, and c may be singular or plural.

In addition, to clearly describe the solutions in embodiments, terms such as “first” and “second” are used in embodiments to distinguish between same items or similar items that provide same functions or purposes. A person skilled in the art may understand that the terms such as “first” and “second” do not limit a quantity or an execution sequence, and the terms such as “first” and “second” do not indicate a definite difference.

In addition, in embodiments, the term “example” or “for example” is used to represent giving an example, an illustration, or a description. Any embodiment or design scheme described as an “example” or “for example” in embodiments may not be explained as being more preferred or having more advantages than another embodiment or design scheme. Use of the terms such as “example” or “for example” is intended to present a related concept in a manner for ease of understanding.

It may be understood that an “embodiment” means that particular features, structures, or characteristics related to this embodiment are included in at least one embodiment. Therefore, embodiments are not necessarily a same embodiment. In addition, these particular features, structures, or characteristics may be combined in one or more embodiments by using any appropriate manner. It may be understood that sequence numbers of the processes do not mean execution orders in various embodiments. The execution order of the processes may be determined based on functions and internal logic of the processes, and may not be construed as any limitation on implementation processes of embodiments.

It may be understood that, in the embodiments, “when”, “at the time”, “at that time when”, and “if” mean that corresponding processing is performed in an objective situation, are not intended to limit time, do not require a determining in some embodiments, and do not mean any other limitation.

It may be understood that, in some scenarios, some optional features in embodiments may be independently implemented without depending on another feature, for example, a solution on which the optional features are currently based, to resolve a corresponding problem and achieve corresponding effects. Alternatively, in some scenarios, the optional features may be combined with another feature based on a requirement. Correspondingly, an apparatus provided in embodiments may also correspondingly implement these features or functions. Details are not described herein.

In the embodiments, unless otherwise specified, for same or similar parts of embodiments, mutual reference may be made between the embodiments. In embodiments, unless otherwise specified or a logical conflict occurs, terms and/or descriptions in different embodiments are consistent and may be referenced by each other, and different embodiments may be combined based on internal logical relationships between the embodiments to form a new embodiment. The following embodiments do not constitute a limitation on the scope of the embodiments.

Wireless sensing is an important technology in the future. In wireless sensing, a sending device may send a signal (referred to as a sent signal), and a receiving device may receive a signal (referred to as a received signal) obtained through reflection of the sent signal by an environment. Then, a transceiver device may compare an association relationship between the received signal and the sent signal, to analyze related information about the ambient environment, for example, analyze whether there is a to-be-detected or to-be-sensed object in the ambient environment, a distance between a scatterer and the transceiver device, an orientation or an angle of the scatterer relative to the transceiver device, and a moving speed of the scatterer relative to the transceiver device.

Wireless sensing may be widely applied to various fields. For example, in a vehicle-to-everything scenario, a vehicle may obtain, through wireless sensing, information about an ambient environment, for example, position information and speed information of a moving object like another vehicle or a pedestrian, and information about a relatively static object like a road surface or a fence. For another example, in an environment like an airport, a special device may be deployed to sense and monitor a flight object like an unmanned aerial vehicle, so that another flight object does not cause security impact on take-off and landing of an aircraft. For another example, in a home environment, intruder detection may be performed through wireless sensing, to improve security and privacy of the home environment.

Wireless sensing may be implemented by using a frequency-modulated continuous wave (FMCW), a pulse waveform, an orthogonal frequency division multiplexing (OFDM) waveform, or the like. In the future, wireless sensing may be an important part of a future mobile communication system. To implement harmonious coexistence of communication and sensing and sharing of radio frequency and baseband devices, in the mobile communication system, it may be considered that a waveform that is the same as a communication waveform is used to implement wireless sensing, in other words, the OFDM waveform is used to implement wireless sensing.

In the OFDM waveform, a time-frequency resource may be divided into different subcarriers in frequency domain, and may be divided into different OFDM symbols in time domain. Further, in a cyclic prefix (CP)-OFDM waveform, the OFDM symbol in time domain includes a CP, which is used to resist multipath delay spread.

In addition, the time-frequency resource may be divided into a time-frequency resource grid. In the OFDM waveform, a minimum time-frequency resource unit is a resource element (RE). One RE includes one subcarrier in frequency domain and one OFDM symbol in time domain. A length (excluding a CP) of one OFDM symbol may be inversely proportional to a subcarrier spacing. For example, if the subcarrier spacing is Δf_{C}, the length of the OFDM symbol is T=1/Δf_{C}.

In wireless sensing, a signal having a large bandwidth may be used to sense the ambient environment. This is because, theoretically, a larger bandwidth indicates a higher delay resolution of a reflection path caused by the scatterer and indicates better sensing performance. In a wireless sensing scenario based on the OFDM waveform, a sensing device may send a signal in a comb manner or an interlace manner. For example, the CP-OFDM waveform is used as an example. As shown in FIG. 1, one subcarrier in every M (for example, M=2) consecutive subcarriers may be used by the sensing device to send a sensing signal, and the other subcarriers in the M consecutive subcarriers may be used by another sensing device or communication device to send a signal.

When the sensing signal is sent in the comb or interlace manner, the sensing signal may have a large bandwidth, and the sensing signal occupies a small quantity of subcarriers in the bandwidth, so that the other subcarriers may be used by another sensing device or the communication device, thereby increasing user capacities in a sensing system and a communication system.

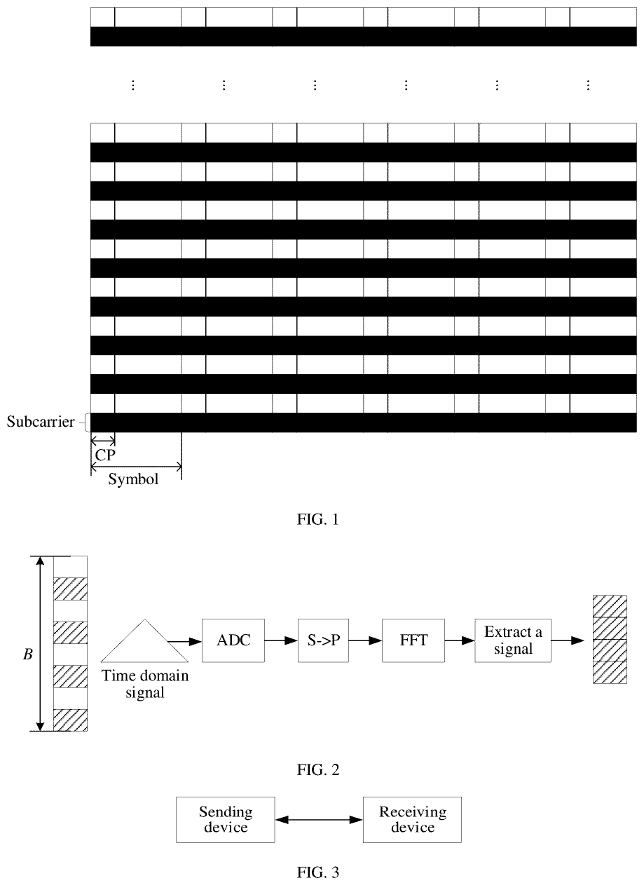

Currently, a signal receiving process based on the OFDM waveform is shown in FIG. 2. For example, a receiver operates in a band with a bandwidth of B=NΔf_{C}, where Δf_{C} represents a subcarrier spacing, and N represents a total quantity of subcarriers included in the bandwidth. Refer to FIG. 2. The receiver first receives a time domain analog signal with a bandwidth of B=NΔf_{C}, and then inputs the time domain analog signal into an analog-to-digital converter (ADC) to sample the analog signal, so as to obtain a time domain digital signal.

The time domain digital signal obtained through sampling may be a serial signal. Therefore, the receiver may perform serial-to-parallel (S->P) conversion. After fast Fourier transform (FFT) is performed on a converted signal, a frequency domain digital signal (which may also be understood as a signal received value on each subcarrier) may be obtained. The frequency domain digital signal includes signals on all subcarriers on the bandwidth. When the sensing signal is sent in the comb or interlace manner, the receiver may extract a signal on a subcarrier corresponding to a comb or an interlace to obtain the sensing signal, and then perform subsequent processing based on the sensing signal.

In the foregoing process, during sampling, according to a Nyquist sampling theorem, a sampling frequency may be greater than or equal to the signal bandwidth B; otherwise, a sampled digital signal is a signal obtained through aliasing of an original signal in frequency domain, affecting receiving performance. In addition, a quantity of FFT points may be greater than or equal to a total quantity N of subcarriers included in the signal bandwidth.

However, a higher sampling frequency of the ADC indicates higher costs of the ADC and lower sampling precision. In addition, due to limited quantization precision of the ADC, additional quantization noise may be generated after a signal passes through the ADC. The quantization noise may depend on a quantity of quantization bits of the ADC and a peak power of a signal input to the ADC. In the foregoing signal receiving process, when frequency division multiplexing is performed, on a same OFDM symbol, on a sensing signal to be received by the receiver and a signal of another user, the peak power of the signal input to the ADC is a sum of powers of the sensing signal and the signal of another user. If the power of the signal of another user is excessively high, the quantization noise generated after the signal passes through the ADC is also large, and even a problem of ADC blocking is caused, in other words, a power of the quantization noise is far greater than a power of a target sensing signal, affecting receiving performance.

Based on this, the embodiments provide a signal receiving method. When a target signal is sent in a comb manner or an interlace manner, time domain extension may be performed on a received signal (including the target signal and a signal of another user), and time domain signals obtained through extension are superposed, to obtain a time domain aliased signal. Then, the time domain aliased signal is sampled to obtain the target signal. Performing sampling in frequency domain is equivalent to performing periodic extension on a signal in time domain, and extracting the target signal from an entire bandwidth may be understood as sampling in frequency domain. Therefore, after extension and aliasing are performed in time domain, it may be considered that the target signal has been extracted. In this case, a signal input to an ADC does not include a signal of another user. In other words, a peak power of the signal input to the ADC is a power of the target signal, and does not include a power of the signal of another user. In this way, the peak power of the signal input to the ADC can be reduced, so as to reduce quantization noise and improve signal receiving performance.

The solutions in embodiments may be applied to various systems. The system may be a 3rd generation partnership project (3GPP) system, for example, a 5th generation (5G) or 6th generation (6G) mobile communication system, a sidelink (SL) system, an ultra-wideband (UWB) system, a vehicle-to-everything (V2X) system, a device-to-device (D2D) communication system, a machine-to-machine (M2M) communication system, an Internet of Things (IoT), or another next generation communication system. The communication system may alternatively be a non-3GPP communication system, for example, a wireless local area network (WLAN) system like Wi-Fi. This is not limited.

The solutions in embodiments may be applied to sensing or communication in various scenarios, for example, may be applied to sensing or communication in one or more scenarios such as smart home, D2D, V2X, and IoT.

The foregoing systems and scenarios applicable to the embodiments are examples for description. Systems and scenarios applicable to the embodiments are not limited thereto. This is uniformly described herein. Details are not described below again.

FIG. 3 shows a system according to an embodiment. The system includes a sending device and a receiving device. The system may be a communication system, a sensing system, or an integrated sensing and communication system.

In a possible embodiment, in the sensing system or the integrated sensing and communication system, the sending device and the receiving device may be a same device, for example, in a self-sending and self-receiving scenario; or the sending device and the receiving device may be different devices, for example, in a self-sending and other-receiving scenario. In the communication system, the sending device and the receiving device may be different devices.

In a possible embodiment, both the sending device and the receiving device may be terminal devices, or both may be network devices. Alternatively, one of the sending device and the receiving device may be a terminal device, and the other may be a network device. This is not limited. Alternatively, the sending device and/or the receiving device may be a sensing device, for example, a radar, or a device having a radar function.

Optionally, the receiving device may be a communication apparatus or a sensing apparatus. The communication apparatus may have a channel coding capability and a channel modulation/demodulation capability. Further, the communication apparatus may have a sensing capability. The sensing apparatus may have a sensing capability. Further, the sensing apparatus may not have a channel coding capability or a channel modulation/demodulation capability, or may have a channel coding capability and a channel modulation/demodulation capability. This is not limited.

In embodiments, the terminal device may be a user side device having a wireless transceiver function, or may be a chip or chip system disposed in the device. The terminal device may also be referred to as user equipment (UE), a terminal, an access terminal, a subscriber unit, a subscriber station, a mobile station (MS), a remote station, a remote terminal, a mobile terminal (MT), a user terminal, a wireless communication device, a user agent, a user apparatus, or the like. The terminal device may be, for example, a terminal device in IoT, V2X, D2D, M2M, a 5G network, or a future evolved public land mobile network (PLMN). The terminal device may be deployed on land, including an indoor device, an outdoor device, a handheld device, or a vehicle-mounted device; may be deployed on a water surface (for example, on a ship); or may be deployed in the air (for example, on an aircraft, a balloon, or a satellite).

For example, the terminal device may be an unmanned aerial vehicle, an IoT device (for example, a sensor, an electricity meter, or a water meter), a V2X device, a station (ST) in a wireless local area network (WLAN), a cellular phone, a cordless phone, a session initiation protocol (SIP) phone, a wireless local loop (WLL) station, a personal digital assistant (PDA) device, a handheld device having a wireless communication function, a computing device, another processing device connected to a wireless modem, a vehicle-mounted device, a wearable device (which may also be referred to as a wearable intelligent device), a tablet computer, a computer having a wireless transceiver function, a virtual reality (VR) terminal, a wireless terminal in industrial control, a wireless terminal in self-driving, a wireless terminal in telemedicine (remote medical), a wireless terminal in a smart grid, a wireless terminal in transportation safety, a wireless terminal in a smart city, a wireless terminal in a smart home, a vehicle-mounted terminal, a vehicle having a vehicle-to-vehicle (V2V) communication capability, an intelligent networked vehicle, or an unmanned aerial vehicle having an unmanned aerial vehicle (UAV) to unmanned aerial vehicle (UAV to UAV, U2U) communication capability. The terminal device may be mobile, or may be fixed. This is not limited.

In embodiments, the network device may be a network side device having a wireless transceiver function, or may be a chip or chip system disposed in the device. The network device is located in a radio access network (RAN) in a mobile communication system, and is configured to provide an access service for the terminal device. The network device may be an evolved NodeB (evolved NodeB, eNB or eNodeB) in an LTE or evolved LTE (LTE-Advanced, LTE-A) system, for example, a conventional macro base station eNB and a micro base station eNB in a heterogeneous network scenario; may be a next generation NodeB (gNodeB or gNB) in a 5G system; may be a transmission reception point (TRP); may be a base station in a future evolved PLMN; may be a broadband network service gateway (BNG), an aggregation switch, or a non-3GPP access device; may be a radio controller in a cloud radio access network (CRAN); may be an access node (AP) in a Wi-Fi system; may be a wireless relay node or a wireless backhaul node; or may be a device that implements a base station function in IoT, V2X, D2D, or M2M. This is not limited. For example, the base station in embodiments may include base stations in various forms, for example, a macro base station, a micro base station (also referred to as a small cell), a relay station, and an access point. This is not limited.

In some embodiments, the network device may alternatively be a module or unit that can implement some or all functions of the base station. For example, the network device may be a central unit (CU), a distributed unit (DU), a CU and a DU, a CU-control plane (CP), a CU-user plane (UP), or a radio unit (RU). The CU and the DU may be separately disposed, or may be included in a same network element, for example, a baseband unit (BBU). The RU may be included in a radio frequency device or a radio frequency unit, for example, included in a remote radio unit (RRU), an active antenna unit (AAU), or a remote radio head (RRH).

In different systems, the CU (or the CU-CP and the CU-UP), the DU, or the RU may alternatively have different names, but a person skilled in the art may understand meanings thereof. For example, the network device may be a network device in an open radio access network (open RAN, ORAN) system or a module of the network device. In the ORAN system, the CU may also be referred to as an open (O)-CU, the DU may also be referred to as an O-DU, the CU-CP may also be referred to as an O-CU-CP, the CU-UP may also be referred to as an O-CU-UP, and the RU may also be referred to as an O-RU. Any one of the CU (or the CU-CP or the CU-UP), the DU, and the RU in the embodiments may be implemented by using a software module, a hardware module, or a combination of a software module and a hardware module.

In some embodiments, the network device may also be referred to as a RAN node, a RAN device, or an access network device, or the network device may be named in another manner. This is not limited.

All or some functions of the terminal device or the network device in the embodiments may alternatively be implemented through a software function running on hardware, or implemented through a virtualized function instantiated on a platform (for example, a cloud platform). The terminal device or the network device in the embodiments may alternatively be a logical node, a logical module, or software that can implement all or some functions of the terminal device or the network device.

With reference to the accompanying drawings, the following describes in detail a signal receiving method provided in embodiments by using interaction between the sending device and the receiving device shown in FIG. 3 as an example.

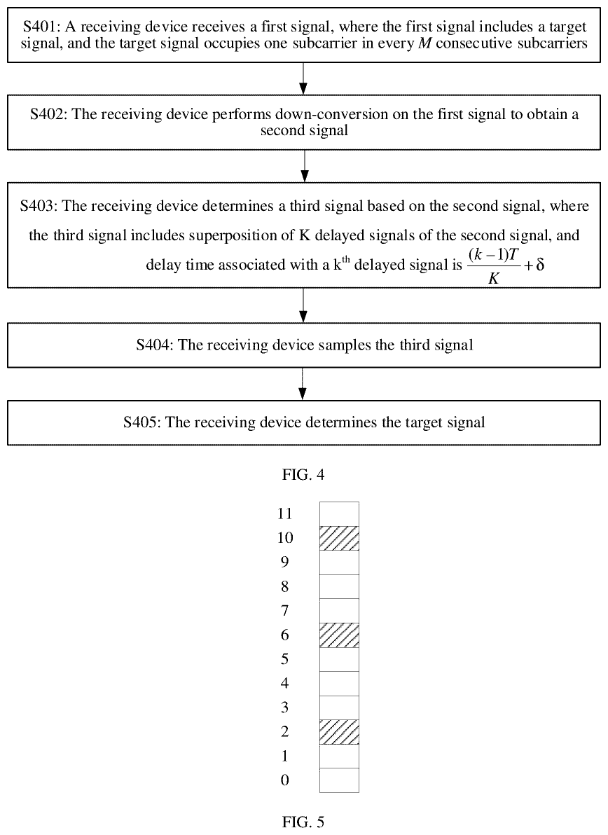

FIG. 4 is a schematic flowchart of a signal receiving method according to an embodiment. The signal receiving method includes the following steps or operations.

S401: a receiving device receives a first signal.

A bandwidth of the first signal is B. The first signal includes a target signal. The target signal occupies one subcarrier in every M consecutive subcarriers, and M is a positive integer greater than 1.

For example, the first signal may be sent by another sending device. In this scenario, it may be considered that a sending device and the receiving device are different devices. Alternatively, the first signal may be a signal obtained through reflection, by an environment, of a signal sent by the receiving device. In this scenario, it may be considered that a sending device and the receiving device are a same device. This is not limited.

In a possible embodiment, the target signal occupies one subcarrier in every M consecutive subcarriers in the bandwidth B. For example, the target signal may occupy one subcarrier at intervals of M−1 consecutive subcarriers in the bandwidth B. In other words, it may be considered that the target signal is distributed in a comb manner or an interlace manner in the bandwidth B, or that the target signal is mapped in the comb or interlace manner in the bandwidth B. A comb index (which may also be understood as an interlace index) associated with the target signal may be determined based on a position of the subcarrier occupied by the target signal, and the position of the subcarrier occupied by the target signal may also be determined based on the comb index associated with the target signal. For example, assuming that subcarriers in the bandwidth B may be respectively associated with indexes 0, 1, 2, . . . , when the target signal occupies subcarriers 0, M, 2M, . . . , a comb index or an interlace index associated with the target signal may be 0, or when a comb index associated with the target signal is 0, the target signal occupies subcarriers 0, M, 2M, . . . ; when the target signal occupies subcarriers 1,M+1,2M+1, . . . , a comb index or an interlace index associated with the target signal may be 1; and so on. As shown in FIG. 5, for example, M=4. The target signal occupies one subcarrier in every four consecutive subcarriers, the target signal occupies subcarriers 2, 6, 10, . . . , and a comb index or an interlace index associated with the target signal is 2.

In a possible embodiment, M may also be understood as a comb number. The subcarrier occupied by the target signal may also be understood as an interlace in which the target signal is located.

In a possible embodiment, in the bandwidth, another subcarrier other than the subcarrier occupied by the target signal may carry a signal of another user or device. For example, in FIG. 5, a comb 0 (including subcarriers 0, 4, 8, . . . ), a comb 1 (including subcarriers 1, 5, 9, . . . ), and a comb 3 (including subcarriers 3, 7, 11, . . . ) in the bandwidth B may be respectively used to carry signals of other three users.

S402: the receiving device performs down-conversion on the first signal to obtain a second signal.

In a possible embodiment, a frequency f_{C} of the down-conversion is the same as a carrier frequency f₀ of the first signal.

In a possible embodiment, a frequency f_{C} of the down-conversion is related to a carrier frequency f₀ of the first signal and/or a position of the target signal. For example, the frequency of the down-conversion may be the same as a frequency of a subcarrier included (or occupied) by the target signal.

In an example, the frequency of the down-conversion may be a frequency of a center subcarrier of the target signal. For example, the target signal occupies Y subcarriers. When Y is an odd number, the center subcarrier of the target signal is a ┌Y/2┐^{th} subcarrier in the Y subcarriers, and ┌ ┐ represents rounding up. When Y is an even number, the center subcarrier of the target signal is a (Y/2)^{th} or (Y/2+1)^{th} subcarrier in the Y subcarriers. Based on the example shown in FIG. 5, if the target signal occupies only subcarriers 2, 6, and 10, the center subcarrier is the subcarrier 6; or if the target signal occupies subcarriers 2, 6, 10, and 14, the center subcarrier is the subcarrier 6 or 10.

In another example, the frequency of the down-conversion may be a frequency of a subcarrier that is in subcarriers included in the target signal and that is closest to a subcarrier corresponding to the carrier frequency f₀. In a special case, if a frequency of one subcarrier in the subcarriers included in the target signal is the same as the carrier frequency f₀, or includes the carrier frequency f₀, the frequency of the down-conversion may be the carrier frequency f₀. Based on the example shown in FIG. 5, if the carrier frequency f₀ is a frequency of the subcarrier 5, a subcarrier whose frequency is closest to the carrier frequency is the subcarrier 6, and the frequency of the down-conversion is a frequency of the subcarrier 6.

In still another example, the frequency of the down-conversion may be a frequency of a subcarrier that is closest to a subcarrier corresponding to the carrier frequency f₀ and that is in subcarriers that are included in the target signal and whose frequencies are greater than (or greater than or equal to) the carrier frequency. In a special case, if a frequency of one subcarrier in the subcarriers included in the target signal is the same as the carrier frequency f₀, or includes the carrier frequency f₀, the frequency of the down-conversion may be the carrier frequency f₀. Based on the example shown in FIG. 5, if the carrier frequency f₀ is a frequency of the subcarrier 5, in the subcarriers occupied by the target signal, subcarriers whose frequencies are greater than the carrier frequency include the subcarrier 6 and the subcarrier 10, and a subcarrier whose frequency is closest to the carrier frequency is the subcarrier 6. Therefore, the frequency of the down-conversion is a frequency of the subcarrier 6.

In yet another example, the frequency of the down-conversion may be a frequency of a subcarrier that is closest to a subcarrier corresponding to the carrier frequency f₀ and that is in subcarriers that are included in the target signal and whose frequencies are less than (or less than or equal to) the carrier frequency. In a special case, if a frequency of one subcarrier in the subcarriers included in the target signal is the same as the carrier frequency f₀, or includes the carrier frequency f₀, the frequency of the down-conversion may be the carrier frequency f₀. Based on the example shown in FIG. 5, if the carrier frequency f₀ is a frequency of the subcarrier 5, in the subcarriers occupied by the target signal, a subcarrier whose frequency is less than the carrier frequency includes the subcarrier 2, and a subcarrier whose frequency is closest to the carrier frequency is the subcarrier 2. Therefore, the frequency of the down-conversion is a frequency of the subcarrier 2.

Optionally, a frequency of a subcarrier in this embodiment may be understood as a center frequency of the subcarrier, a start frequency of the subcarrier, an end frequency of the subcarrier, or another frequency included in the subcarrier.

In a possible embodiment, performing down-conversion on the first signal may include: multiplying the first signal by a single-frequency signal, where a frequency of the single-frequency signal is the frequency of the down-conversion. For example, the frequency of the down-conversion is f_{C}. The single-frequency signal may be represented as y(t)=exp(−2πjf_{C}t), where t represents time.

The single-frequency signal is represented in a complex number form. There is no complex-number-domain signal in the physical world. Therefore, in some embodiments, the first signal may be separately multiplied by cos(2πf_{C}t) and sin(2πf_{C}t), and then an I signal and a Q signal are separately obtained by using a low-pass filter. In other words, the second signal may include the I signal and the Q signal.

Optionally, when the frequency of the down-conversion is f_{C}, down-conversion may be performed on the first signal once to obtain the second signal, and the frequency of the down-conversion this time is f_{C}. Alternatively, down-conversion at the frequency of f₀ may be first performed on the first signal to obtain an intermediate signal, and then down-conversion at a frequency of f_{C}−f₀ is performed on the intermediate signal to obtain the second signal.

After the down-conversion, a radio frequency signal (for example, the first signal) having a high frequency may be shifted to a baseband for processing. In addition, the frequency of the down-conversion is determined based on the carrier frequency of the first signal and the position of the target signal, and the target signal may be aligned with a baseband zero frequency after the down-conversion, to facilitate subsequent processing.

S403: the receiving device determines a third signal based on the second signal.

The third signal includes superposition of K delayed signals of the second signal. Delay time associated with a k^{th} delayed signal in the K delayed signals is

$$\frac{( k - 1 ) T}{K} + δ .$$

T is a time length of the first signal, k=1, 2, . . . , or K, δ is greater than or equal to 0, and K is a positive integer greater than or equal to M.

In a possible embodiment, delay time associated with a delayed signal of the second signal may be understood as follows: the delayed signal may be obtained by delaying the second signal by the delay time. For example, delaying a signal may also be understood as shifting the signal backward in time domain.

In a possible embodiment, the time length of the first signal is a length of one OFDM symbol. In other words, the first signal may be understood as a signal on one OFDM symbol. The length of one OFDM symbol may be a length of a part excluding a CP part, for example, T=1/Δf_{C}. When the receiving device receives signals on a plurality of OFDM symbols, a signal on each OFDM symbol may be understood as the first signal. In other words, a received signal on each OFDM symbol is applicable to the signal receiving method provided in this embodiment.

In a possible embodiment, a value of k may alternatively start from 0, for example, k=0, 1, 2, . . . , or K−1. In this scenario, the delay time associated with the k^{th} delayed signal is

$$\frac{kT}{K} + δ ,$$

and parts related to k in texts and formulas in the subsequent embodiments may be adaptively adjusted accordingly. In the following embodiments, an example in which k=1, 2, . . . , or K is used for description.

In a possible embodiment, K=M; or K=M−1+C, where C is a positive integer, and further, C is a positive integer less than or equal to M. For example, C=M, for example, K=2M−1.

It may be understood that the first signal, the second signal, and the third signal are described from a perspective of a time domain analog signal.

In a possible embodiment, sampling a signal in frequency domain is equivalent to performing periodic extension on the signal in time domain, and extracting the target signal from an entire bandwidth may be understood as sampling in frequency domain. Accordingly, in time domain, this may be equivalent to performing periodic extension in time domain. An aliased signal may be obtained by superposing signals obtained through periodic extension. After discrete Fourier transform (DFT) is performed on a sequence including time domain sampling points of the aliased signal in one period, a discrete frequency domain sequence number or a discrete frequency domain sequence corresponding to the target signal is obtained. In other words, a signal of the aliased signal in one period may be determined by using the third signal, and the discrete frequency domain sequence number or the discrete frequency domain sequence corresponding to the target signal may be further determined. For example, after determining the third signal, the receiving device may perform the following step or operation S404 and step or operation S405.

S404: the receiving device samples the third signal.

In a possible embodiment, sampling the third signal may be understood as: converting the third signal from a time domain analog signal into a time domain digital signal (or referred to as a discrete time domain signal or a discrete time domain sequence).

In a possible embodiment, an N/M-point discrete time domain sequence may be obtained by sampling the third signal in step or operation S404. N is greater than or equal to a quantity of subcarriers included in the bandwidth of the first signal, and N is a positive integer. The N/M-point discrete time domain sequence may be understood as the time domain sampling points of the aliased signal in one period. In a special case, when N/M is not an integer, N/M may be rounded up or rounded down. In other words, an ┌N/M┐-point discrete time domain sequence or an └N/M┘-point discrete time domain sequence is obtained by sampling the third signal. In this embodiment, that N/M is an integer is used for description.

S405: the receiving device determines the target signal. The target signal may be a discrete time domain signal or a discrete time domain sequence corresponding to the target signal, or may be a discrete frequency domain signal or a discrete frequency domain sequence corresponding to the target signal.

Optionally, when the target signal is the discrete time domain signal or the discrete time domain sequence corresponding to the target signal, the target signal may be obtained by sampling the third signal in step or operation S404. Step or operation S405 may not be performed. Alternatively, step or operation S405 may be understood as: determining, as the target signal, the discrete time domain signal or the discrete time domain sequence obtained by sampling the third signal.

Optionally, when the target signal is the discrete frequency domain signal or the discrete frequency domain sequence corresponding to the target signal, the discrete time domain signal or the discrete time domain sequence obtained by sampling the third signal in step or operation S404 is referred to as a first time domain sequence. That the receiving device may determine the target signal based on the first time domain sequence may also be understood as that the receiving device determines the discrete frequency domain signal or the discrete frequency domain sequence corresponding to the target signal.

In a possible embodiment, the receiving device may perform N/M-point DFT on the first time domain sequence to obtain the target signal, in other words, to obtain the discrete frequency domain signal or the discrete frequency domain sequence corresponding to the target signal. N is greater than or equal to a quantity of subcarriers included in the bandwidth of the first signal, and N is a positive integer. In a special case, when N/M is not an integer, N/M may be rounded up or rounded down. In other words, ┌N/M┐-point DFT or └N/M┘-point DFT is performed. In this embodiment, that N/M is an integer is used for description.

In a possible embodiment, performing N/M-point DFT on the first time domain sequence may include: performing N/M-point FFT on the first time domain sequence, where FFT may be understood as an implementation of DFT.

In a possible embodiment, performing N/M-point DFT on the first time domain sequence may be understood as performing N/M-point DFT on the sequence including the time domain sampling points of the aliased signal in one period.

Based on the foregoing solution, when the target signal is sent in a comb manner or an interlace manner, time domain extension may be performed on the received signal (for example, the first signal), and time domain signals obtained through extension are superposed, to obtain an aliased time domain signal. Then, the aliased time domain signal is sampled to obtain the target signal. Performing sampling in frequency domain is equivalent to performing periodic extension on a signal in time domain, and extracting the target signal from an entire bandwidth may be understood as sampling in frequency domain. Therefore, after extension and aliasing are performed in time domain, it may be considered that the target signal has been extracted. In this case, a signal input to an ADC does not include a signal of another user. In other words, a peak power of the signal input to the ADC is a power of the target signal, and does not include a power of the signal of another user. In this way, the peak power of the signal input to the ADC can be reduced, so as to reduce quantization noise and improve signal receiving performance.

The foregoing describes an overall procedure of the signal receiving method provided in this embodiment. The following describes in detail determining and sampling the third signal.

A manner of determining the third signal is as follows:

In a first possible embodiment, determining the third signal based on the second signal may include: delaying the second signal K times to obtain the K delayed signals of the second signal, and superposing the K delayed signals to obtain the third signal.

The delay time associated with the k^{th} delayed signal is

$$\frac{( k - 1 ) T}{K} + δ .$$

In other words, the second signal may be delayed by δ,

$$\frac{T}{K} + δ , \frac{2 T}{K} + δ , ... , and \frac{( K - 1 ) T}{K} + δ$$

respectively to obtain the K delayed signals of the second signal.

In a possible embodiment, when δ=0, the signal obtained by delaying the second signal by δ may be understood as the second signal. In other words, it may be considered that a 1^{st} delayed signal of the second signal is obtained without delaying the second signal. However, for brevity and consistency of expression, in this case, the 1^{st} delayed signal of the second signal is still referred to as a delayed signal of the second signal.

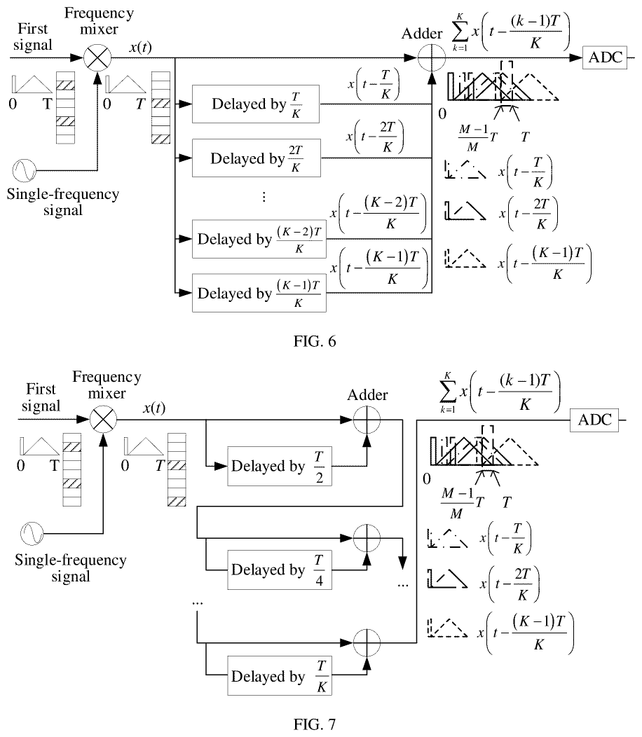

For example, δ=0 and K=M=4. As shown in FIG. 6, after receiving the first signal, the receiving device inputs the first signal to a frequency mixer to perform down-conversion on the first signal, to obtain a second signal x(t). Then, the second signal is delayed by 0,

$$\frac{T}{K} , \frac{2 T}{K} , ... , and \frac{( K - 1 ) T}{K}$$

respectively to obtain x(t),

$$x ( t - \frac{T}{K} ) , x ( t - \frac{2 T}{K} ) , ... , and x ( t - \frac{( K - 1 ) T}{K} ) ,$$

and the K signals are input to an adder for superposition to obtain the third signal. For example, the third signal may be represented as:

$${\sum }_{k = 1}^{K} x ( t - \frac{( k - 1 ) T}{K} - δ ) .$$

A reference point of t is start time of the first signal. In other words, a moment 0 corresponding to t (or understood as a moment of t=0) is the start time of the first signal.

Optionally, the start time of the first signal may be start time of a part excluding a CP part. For example, assuming that start time of an OFDM symbol (including a CP) in which the first signal is located is t1, start time of the CP is t1, and end time of the CP is t2, the start time of the first signal may be t2, in other words, a reference point of a first time range may be t2.

In a second possible embodiment, determining the third signal based on the second signal may include: determining the third signal by using an X-stage circuit. In the X-stage circuit,
an output signal of an i^{th}-stage circuit is a signal obtained by superposing an input signal of the i^{th}-stage circuit and a signal obtained by delaying the input signal of the i^{th}-stage circuit, where i=1, 2, . . . , or X, and X is a positive integer greater than 1. For example, the input signal of the i^{th}-stage circuit may be delayed to obtain a delayed signal of the input signal, and then the input signal and the delayed signal of the input signal are superposed to obtain the output signal.

When i=1, the input signal of the i^{th}-stage circuit is a signal obtained by delaying the second signal by δ. When i>1 the input signal of the i^{th}-stage circuit is an output signal of an (i−1)^{th}-stage circuit. The third signal is an output signal of an X^{th}-stage circuit. The output signal of the X^{th}-stage circuit includes superposition of the K delayed signals of the second signal.

In a first possible embodiment, when K=2^{X}, the output signal of the i^{th}-stage circuit is a signal obtained by superposing the input signal of the i^{th}-stage circuit and a signal obtained by delaying the input signal of the i^{th}-stage circuit by

$$\frac{T}{{2}^{i}} .$$

For example, δ=0 and K=M=4, as shown in FIG. 7.

When i=1, an input signal of a 1^{st}-stage circuit is a second signal x(t), and a delayed signal

$$x ( t - \frac{T}{2} )$$

is obtained by delaying the second signal x(t) by T/2. Therefore, an output signal of the 1^{st}-stage circuit is

$$x ( t ) + x ( t - \frac{T}{2} ) .$$

When i=2, an input signal of a 2^{nd}-stage circuit is the output signal of the 1^{st}-stage circuit, for example,

$$x ( t ) + x ( t - \frac{T}{2} ) ,$$

and a delayed signal

$$x ( t - \frac{T}{4} ) + x ( t - \frac{3 T}{4} )$$

is obtained by delaying the input signal of the 2^{nd}-stage circuit by

$$\frac{T}{{2}^{2}} .$$

Therefore, an output Singal of the 2^{nd}-stage circuit is

$$x ( t ) + x ( t - \frac{T}{2} ) + x ( t - \frac{T}{4} ) + x ( t - \frac{3 T}{4} ) .$$

By analogy, the output signal of the X^{th}-stage circuit (for example, the third signal) may be represented as

$${\sum }_{k = 1}^{K} x ( t - \frac{( k - 1 ) T}{K} ) .$$

In a second possible embodiment, K may be represented as a product of X positive integers, for example,

$$K = {\prod }_{i = 1}^{X} {K}_{i} ,$$

where Π represents cumulative multiplication. Kᵢ is a positive integer, and further, Kᵢ is a positive integer greater than 1. In this scenario, the output signal of the i^{th}-stage circuit is a signal obtained by superposing the input signal of the i^{th}-stage circuit and signals obtained by respectively delaying the input signal of the i^{th}-stage circuit by

$$\frac{T}{{\prod }_{j = 1}^{i} {K}_{j}} , \frac{2 T}{{\prod }_{j = 1}^{i} {K}_{j}} , ... , and \frac{( {K}_{i} - 1 ) T}{{\prod }_{j = 1}^{i} {K}_{j}} .$$

In other words, in the signal of the i^{th}-stage circuit by i^{th}-stage circuit, the input signal of the i^{th}-stage circuit may be delayed a plurality of times.

In the foregoing descriptions, i=1, 2, . . . , or X. In addition, a value of i may alternatively start from 0, for example, i=0, 1,2, . . . , or X−1. In this scenario, the output signal of the i^{th}-stage circuit is a signal obtained by superposing the input signal of the i^{th}-stage circuit and a signal obtained by delaying the input signal of the i^{th}-stage circuit by

$$\frac{T}{{2}^{i + 1}} ,$$

or a signal obtained by superposing the input signal of the i^{th}-stage circuit and signals obtained by respectively delaying the input signal of the i^{th}-stage circuit by

$$\frac{T}{{\prod }_{j = 0}^{i} {K}_{j}} , \frac{2 T}{{\prod }_{j = 0}^{i} {K}_{j}} , ... , and \frac{( {K}_{i} - 1 ) T}{{\prod }_{j = 0}^{i} {K}_{j}} .$$

Parts related to i in texts and formulas in the subsequent embodiments may be adaptively adjusted accordingly. In the following embodiments, an example in which i=1,2, . . . , or X is used for description.

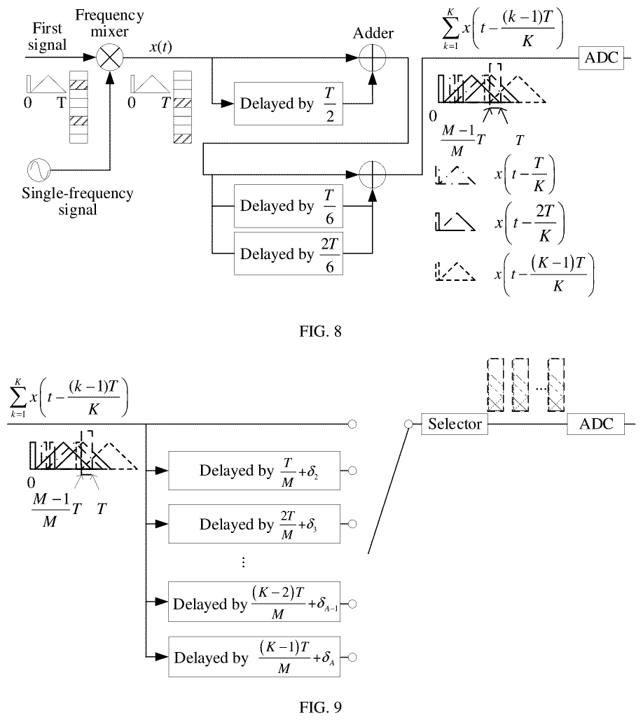

For example, δ=0, K=6, X=2, and Kᵢ=2 or 3, for example, K=2×3, as shown in FIG. 8.

When i=1, Kᵢ=2, an input signal of a 1^{st}-stage circuit may be delayed once, and associated delay time is T/2. The input signal of the 1^{st}-stage circuit is a second signal x(t), and a delayed signal

$$x ( t - \frac{T}{2} )$$

is obtained by delaying the second signal x(t) by T/2. Therefore, an output signal of the 1^{st}-stage circuit is

$$x ( t ) + x ( t - \frac{T}{2} ) .$$

When i=2, Kᵢ=3, an input signal of a 2^{nd}-stage circuit may be delayed twice, and associated delay time is T/6 and

$$\frac{2 T}{6}$$

respectively. The input signal of the 2^{nd}-stage circuit is the output signal of the 1^{st}-stage circuit, for example,

$$x ( t ) + x ( t - \frac{T}{2} ) .$$

A delayed signal

$$x ( t - \frac{T}{6} ) + x ( t - \frac{4 T}{6} )$$

is obtained by delaying the input signal of the 2^{nd}-stage circuit by T/6, and a delayed signal

$$x ( t - \frac{2 T}{6} ) + x ( t - \frac{5 T}{6} )$$

obtained by delaying the input signal of the 2^{nd}-stage circuit by

$$\frac{2 T}{6} .$$

Therefore, an output signal of the 2^{nd}-stage circuit is

$$x ( t ) + x ( t - \frac{T}{2} ) + x ( t - \frac{T}{6} ) + x ( t - \frac{4 T}{6} ) + x ( t - \frac{2 T}{6} ) + x ( t - \frac{5 T}{6} ) ,$$

for example,

$$x ( t ) + x ( t - \frac{T}{6} ) + x ( t - \frac{2 T}{6} ) + x ( t - \frac{3 T}{6} ) x ( t - \frac{4 T}{6} ) + x ( t - \frac{5 T}{6} ) ,$$

for example,

$${\sum }_{k = 1}^{K} x ( t - \frac{( k - 1 ) T}{K} ) .$$

In a third possible embodiment, the third signal may be determined by using a combination of the first possible embodiment and the second possible embodiment. In this scenario, K may be represented as K′+2^{X}. In this case, an intermediate signal 1 may be obtained first by using the first possible embodiment, where the intermediate signal 1 is obtained by superposing K′ delayed signals of the second signal, and delay time associated with a k^{th} (k=1, 2, . . . , or K′) delayed signal is

$$\frac{( k - 1 ) T}{K} + δ .$$

Then, the second signal is delayed by

$$\frac{{K}^{′} T}{K} + δ$$

to obtain an intermediate signal 2, and the intermediate signal 2 is input to the X-stage circuit for further delay. The output signal of the i^{th}-stage circuit is a signal obtained by superposing the input signal of the i^{th}-stage circuit and a signal obtained by delaying the input signal of the i^{th}-stage circuit by

$$\frac{( K - {K}^{′} ) T}{{2}^{i} K} ,$$

and the output signal or the X^{th}-stage circuit is denoted as an intermediate signal 3. Then, the intermediate signal 1 and the intermediate signal 3 are superposed to obtain the third signal.

Alternatively, the intermediate signal 3 may be obtained in the following manner: an intermediate signal 4 is obtained by using the second possible embodiment, for example, the second signal is first input to the X-stage circuit, where the output signal of the i^{th}-stage circuit is a signal obtained by superposing the input signal of the i^{th}-stage circuit and the signal obtained by delaying the input signal of the i^{th}-stage circuit by

$$\frac{( K - {K}^{′} ) T}{{2}^{i} K} ,$$

and the output signal of the X^{th}-stage circuit is the intermediate signal 4. Then, the intermediate signal 3 may be obtained by delaying the intermediate signal 4 by

$$\frac{{K}^{′} T}{K} .$$

The foregoing manner may also be extended to a case in which

$$K = {K}^{′} + {\prod }_{i = 1}^{X} {K}_{i} ,$$

and details are not described herein again.

For example, δ=0, K=9, K′=1, and X=3, for example, K=1+2³. The second signal x(t) may be first delayed by 0 to obtain the intermediate signal 1, in other words, the intermediate signal 1 is the second signal x(t), then the second signal is delayed by T/9 to obtain the intermediate signal 2, for example,

$$x ( t - \frac{T}{9} ) ,$$

and then the intermediate signal 2 is delayed by using a three-stage circuit to obtain the intermediate signal 3. Delay time corresponding to the three-stage circuit are separately

$$\frac{4 T}{9} , \frac{2 T}{9} , and \frac{T}{9} .$$

When i=1, an input signal of a 1^{st}-stage circuit is

$$x ( t - \frac{T}{9} ) ,$$

and a delayed signal

$$x ( t - \frac{5 T}{9} )$$

is obtained by delaying the input signal by

$$\frac{4 T}{9} .$$

Therefore, an output signal of the 1^{st}-stage circuit is

$$x ( t - \frac{T}{9} ) + x ( t - \frac{5 T}{9} ) .$$

When i=2, an input signal of a 2^{nd}-stage circuit is the output signal of the 1^{st}-stage circuit, for example,

$$x ( t - \frac{T}{9} ) + x ( t - \frac{5 T}{9} ) ,$$

and a delayed signal

$$x ( t - \frac{3 T}{9} ) + x ( t - \frac{7 T}{9} )$$

is obtained by delaying the input signal of the 2^{nd}-stage circuit by

$$\frac{2 T}{9} .$$

Therefore, an output signal of the 2^{nd}-stage circuit is

$$x ( t - \frac{T}{9} ) + x ( t - \frac{5 T}{9} ) + x ( t - \frac{3 T}{9} ) + x ( t - \frac{7 T}{9} ) .$$

When i=3, an input signal of a 3rd-stage circuit is the output signal of the 2^{nd}-stage circuit, for example,

$$x ( t - \frac{T}{9} ) + x ( t - \frac{3 T}{9} ) + x ( t - \frac{5 T}{9} ) + x ( t - \frac{7 T}{9} ) ,$$

and a delayed signal

$$x ( t - \frac{2 T}{9} ) + x ( t - \frac{4 T}{9} ) + x ( t - \frac{6 T}{9} ) + x ( t - \frac{8 T}{9} )$$

is obtained by delaying the input signal of the 3^{rd}-stage circuit by T/9. Therefore, an output signal of the 3^{rd}-stage circuit (for example, the intermediate signal 3) is

$$x ( t - \frac{T}{9} ) + x ( t - \frac{3 T}{9} ) + x ( t - \frac{5 T}{9} ) + x ( t - \frac{7 T}{9} ) + x ( t - \frac{2 T}{9} ) + x ( t - \frac{4 T}{9} ) + x ( t - \frac{6 T}{9} ) + x ( t - \frac{8 T}{9} ) .$$

A signal obtained by superposing the intermediate signal 1 and the intermediate signal 3 is

$$x ( t ) + x ( t - \frac{T}{9} ) + x ( t - \frac{3 T}{9} ) + x ( t - \frac{5 T}{9} ) + x ( t - \frac{7 T}{9} ) + x ( t - \frac{2 T}{9} ) + x ( t - \frac{4 T}{9} ) + x ( t - \frac{6 T}{9} ) + x ( t - \frac{8 T}{9} ) ,$$

for example,

$${\sum }_{k = 1}^{9} x ( t - \frac{( k - 1 ) T}{9} ) .$$

It may be understood that there may be a plurality of manners to implement that “the third signal includes the superposition of the K delayed signals of the second signal, and the delay time associated with the k^{th} delayed signal in the K delayed signals is

$$\frac{( k - 1 ) T}{K} + {δ}^{″} .$$

In addition, it is not required that each delayed signal of the second signal has a corresponding circuit (for example, in the foregoing second embodiment, no delayed signal component is directly generated, but a next generated signal is consistent with a required form). In other words, a manner of determining or obtaining the third signal is not limited.

For sampling of the third signal, there are the following embodiments.

In a first possible embodiment, when K=M, sampling the third signal may include: sampling the third signal within the first time range.

For example, the first time range may be one of the following:

$$[ \frac{M - 1}{M} T + δ , T + δ ] , ( \frac{M - 1}{M} T + δ , T + δ ] , [ \frac{M - 1}{M} T + δ , T + δ ) , or$$

$$( \frac{M - 1}{M} T + δ , T + δ ) .$$

The third signal within the first time range may be understood as a signal of the foregoing aliased signal in one period. For example, when the third signal is sampled within the first time range, and the first time domain range is

$$[ \frac{M - 1}{M} T + δ , T + δ ] ,$$

the sampled signal may be represented as:

$${\sum }_{k = 1}^{K} x ( t - \frac{( k - 1 ) T}{K} - δ ) , where$$

$$t ∈ [ \frac{M - 1}{M} T + δ , T + δ ] .$$

For example, as shown in FIG. 6 to FIG. 8, in signals output by the adder, a signal located in a dashed rectangle box is a sampled signal, or may be understood as a signal of the target signal in time domain.

A reference point of the first time range (or understood as a reference point of t) is the start time of the first signal. In other words, a moment 0 (or understood as a moment t=0) corresponding to the first time range is the start time of the first signal, or a time interval between start time of the first time range and the start time of the first signal is

$$\frac{M - 1}{M} T + δ .$$

Optionally, for a part of the first signal that is outside the first time range (for example, including a CP part in an OFDM symbol in which the first signal is located), whether the receiving device samples the part may depend on an implementation of the receiving device. This is not limited. For example, the discrete time domain signal or the discrete time domain sequence obtained by sampling the third signal within the first time range is referred to as the first time domain sequence.

In a possible embodiment, when the target signal is the discrete time domain signal or the discrete time domain sequence corresponding to the target signal, the first time domain sequence is the discrete time domain signal or the discrete time domain sequence corresponding to the target signal.

In another possible embodiment, when the target signal is the discrete frequency domain signal or the discrete frequency domain sequence corresponding to the target signal, the receiving device may perform N/M-point DFT on the first time domain sequence to obtain the discrete frequency domain signal or the discrete frequency domain sequence corresponding to the target signal. N is greater than or equal to the quantity of subcarriers included in the bandwidth of the first signal, and N is a positive integer.

Based on the possible embodiment, performing sampling in frequency domain is equivalent to performing periodic extension on a signal in time domain, and extracting the target signal from the entire bandwidth may be understood as sampling in frequency domain, and corresponds to (or is equivalent to) periodic extension in time domain. A signal of the third signal within the first time domain range corresponds to a signal of the signal obtained through periodic extension in one period. Therefore, when the third signal is sampled within the first time domain range, it may be considered that a signal input to the ADC does not include a signal of another user. In other words, a peak power of the signal input to the ADC is a peak power of the target signal, and does not include a power of the signal of another user.

In this way, the peak power of the signal input to the ADC can be reduced, so as to reduce quantization noise and improve signal receiving performance.

In addition, a length of the first time domain range may be T/M. In other words, within a time length T of one OFDM symbol, duration in which the ADC used for sampling is turned on or operating is only required to be T/M. In comparison with a case in which the ADC is turned on within the time length T, this case can reduce sampling power consumption of the ADC, to reduce power consumption of the receiving device.

In addition, based on the possible embodiment, if a sampling rate for sampling the third signal within the first time range is NΔf_{C}, when the length of the first time domain range is T/M, the target signal includes N/M sampling points in time domain. Subsequently, only

$$\frac{N}{M} - point DFT$$

may be performed to obtain the frequency domain signal corresponding to the target signal. N is greater than or equal to the quantity of subcarriers included in the bandwidth of the first signal, and N is a positive integer. In comparison with a solution in which at least N-point DFT is performed on a signal on an entire OFDM symbol, this solution can reduce a quantity of DFT points, and reduce a capability requirement and costs for a DFT module (for example, an FFT module).

In a second possible embodiment, when K=M, A delayed signals of the third signal may be separately sampled, and then the target signal is determined based on sampling results of the A delayed signals. A is a positive integer, and further, A is a positive integer less than or equal to M. In a special case, A=M. For example, as shown in FIG. 9, the following steps or operations may be included.
(a) Delay the third signal A times to obtain the A delayed signals of the third signal, where delay time associated with an a^{th} delayed signal is

$$\frac{( a - 1 ) T}{M} + {δ}_{a} ,$$

δₐ is greater than or equal to 0, and a=1, 2, . . . , or A. Similarly, a value of a may alternatively be 0, 1, . . . , or A−1, and the delay time associated with the a^{th} delayed signal is

$$\frac{a T}{M} + {δ}_{a} .$$

Parts related to a in texts and formulas in the subsequent embodiments may be adaptively adjusted accordingly. In the following embodiments, an example in which a=1, 2, . . . , or A is used for description.

In a possible embodiment, when a is in different values, values of δₐ may be the same or may be different. For example, when a=1, δₐ may equal to 0; and when a≠1, δₐ may greater than or equal to 0.
(b) Sample the a^{th} delayed signal of the third signal within a second time range. In other words, each delayed signal of the third signal is sampled. Different delayed signals of the third signal, for example, different values of a, correspond to different second time ranges.

In a possible embodiment, a reference point of the second time range is the start time of the first signal. Refer to related descriptions of the first time range. Details are not described herein again.

In a possible embodiment, the second time range corresponding to the a^{th} delayed signal may be one of the following:

$$[ \frac{M + a - 2}{M} T + δ + {\sum }_{j = 1}^{a} {δ}_{j} , \frac{M + a - 1}{M} T + δ + {\sum }_{j = 1}^{a} {δ}_{j} ] ,$$

$$( \frac{M + a - 2}{M} T + δ + {\sum }_{j = 1}^{a} {δ}_{j} , \frac{M + a - 1}{M} T + δ + {\sum }_{j = 1}^{a} {δ}_{j} ] , [ \text{} \frac{M + a - 2}{M} T +$$

$$δ + {\sum }_{j = 1}^{a} {δ}_{j} , \frac{M + a - 1}{M} T + δ + {\sum }_{j = 1}^{a} {δ}_{j} ) , \text{} or$$

$$( \frac{M + a - 2}{M} T + δ + {\sum }_{j = 1}^{a} {δ}_{j} , \frac{M + a - 1}{M} T + δ + {\sum }_{j = 1}^{a} {δ}_{j} ) .$$

In a possible embodiment, as shown in FIG. 9, the A delayed signals of the third signal may be separately input to the ADC, by using a selector, at different moments (for example, different second time ranges) for sampling.

Optionally, a signal each delayed signal of the third signal within the second time range may also be understood as a signal of an aliased signal in one period (for example, a signal of the target signal in time domain, for example, a signal in a dashed-line box in FIG. 9), where the aliased signal is obtained by performing periodic extension and superposition on second signals. In other words, the target signal is copied A times in time domain.

In a possible embodiment, a sampling frequency used for sampling the a^{th} delayed signal of the third signal is greater than or equal to NΔf_{C}/A; or a sampling frequency for the a^{th} delayed signal of the third signal may be greater than or equal to B/A. N is greater than or equal to the quantity of subcarriers included in the bandwidth of the first signal, and N is a positive integer. Δf_{C} is a bandwidth of the subcarrier, or a subcarrier spacing. B is the bandwidth of the first signal.

Optionally,

$$\frac{N}{A M} - point$$

sampling may be performed on the a^{th} delayed signal of the third signal within the second time range. In other words, a sampling result obtained by sampling the a^{th} delayed signal of the third signal within the second time range includes signals at

$$\frac{N}{A M}$$

sampling points.

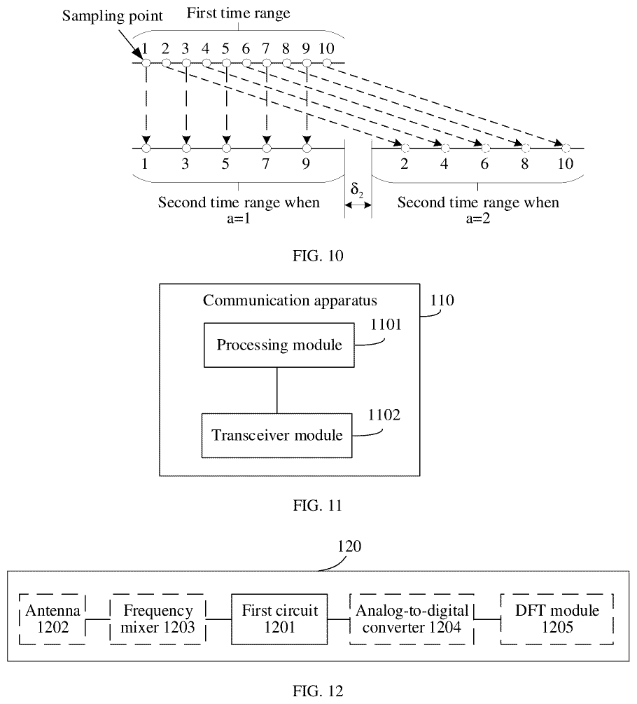

In a possible embodiment, sampling positions of any two delayed signals in the A delayed signals of the third signal are different. For example, as shown in FIG. 10, in an example in which

$$\frac{N}{M} = 10$$

and A=2, 10 points originally may be sampled for the third signal within the first time range. A sampling position of a 1^{st} delayed signal of the third signal within a second time range 1 may correspond to 1^{st}, 3^{rd}, 5^{th}, 7^{th}, and 9^{th} sampling points of the third signal within the first time range, and a sampling position of a 2^{nd} delayed signal of the third signal within a second time range 2 may correspond to 2^{nd}, 4^{th}, 6^{th}, 8^{th}, and 10^{th} sampling points of the third signal within the first time range.

In FIG. 10, an example in which δ₁=0 and δ₂≠0 is used for description. Therefore, when the reference points of the first time range and the second time range are the same, and both are the start time of the first signal, start time of the second time range 1 and the first time range are the same, and a time interval between end time of the second time range 2 and the start time of the second time range 1 is δ₂.
(c) Determine the target signal based on sampling results of the A delayed signals of the third signal.

Optionally, the sampling results of the A delayed signals of the third signal may be re-sorted to obtain the first time domain sequence. For example, the sampling results of the A delayed signals may be sequentially arranged from front to back according to a time domain order of sampling points that are of the third signal within the first time range and that correspond to sampling points within the second time range, to obtain the first time domain sequence.

For example, based on the example shown in FIG. 10, five sampling points may be obtained within the second time range 1, and five sampling points may be obtained within the second time range 2. Then, the 10 sampling points are re-sorted. For example, the two groups of five sampling points are interpolated, and the first time domain sequence may be a sampling result of a 1^{st} sampling point within the second time range 1 (corresponding to a 1^{st} sampling point within the first time range), a sampling result of a 1^{st} sampling point within the second time range 2 (corresponding to a 2^{nd} sampling point within the first time range), a sampling result of a 2^{nd} sampling point within the second time range 1 (corresponding to a 3^{rd} sampling point within the first time range), a sampling result of a 2^{nd} sampling point within the second time range 2 (corresponding to a 4th sampling point within the first time range), a sampling result of a 3^{rd} sampling point within the second time range 1 (corresponding to a 5th sampling point within the first time range), a sampling result of a 3^{rd} sampling point within the second time range 2 (corresponding to a 6^{th} sampling point within the first time range), a sampling result of a 4^{th} sampling point within the second time range 1 (corresponding to a 7^{th} sampling point within the first time range), a sampling result of a 4^{th} sampling point within the second time range 2 (corresponding to an 8^{th} sampling point within the first time range), a sampling result of a 5^{th} sampling point within the second time range 1 (corresponding to a 9^{th} sampling point within the first time range), and a sampling result of a 5^{th} sampling point within the second time range 2 (corresponding to a 10^{th} sampling point within the first time range).

In a possible embodiment, when the target signal is the discrete time domain signal or the discrete time domain sequence corresponding to the target signal, the first time domain sequence is the discrete time domain signal or the discrete time domain sequence corresponding to the target signal.

In another possible embodiment, when the target signal is the discrete frequency domain signal or the discrete frequency domain sequence corresponding to the target signal, the receiving device may perform N/M-point DFT on the first time domain sequence to obtain the discrete frequency domain signal or the discrete frequency domain sequence corresponding to the target signal.

Based on the possible embodiment, the receiving device makes an additional copy of a signal of the target signal in time domain, and samples each copied signal at a frequency of NΔf_{C}/A. In comparison with a case of sampling at a frequency of NΔf_{C}, this case reduces the sampling frequency, to reduce a performance requirement and costs for the ADC.

In addition, based on the possible embodiment, only N/M sampling points are included in time domain. Subsequently, only

$$\frac{N}{M} - point DFT$$

may be performed to obtain the frequency domain signal corresponding to the target signal. In comparison with a solution in which at least N-point DFT is performed on a signal on an entire OFDM symbol, this solution can reduce a quantity of DFT points, and reduce a capability requirement and costs for a DFT module.

In a third possible embodiment, when K=M−1+C, segment sampling may be performed on the third signal, and the target signal is determined based on a result of segment sampling. For example, the following steps or operations may be included.

### (a) Perform C Segments of Sampling on the Third Signal.

A c^{th} segment of sampling corresponds to a signal of the third signal within a third time range c, where c=1, 2, . . . , or C. In other words, the third signal may be divided into C segments of sub-signals in terms of time, and then the C segments of sub-signals are separately sampled. A c^{th} segment of sub-signal is a signal of the third signal within the third time range c.

The third time range c may be one of the following:

$$[ \frac{M + c - 2}{M} T + δ , \frac{M + c - 1}{M} T + δ ] , ( \frac{M + c - 2}{M} T + δ , \frac{M + c - 1}{M} T + δ ] , [ \text{} \frac{M + c - 2}{M} T + δ , \frac{M + c - 1}{M} T + δ ) , or ( \frac{M + c - 2}{M} T + δ , \frac{M + c - 1}{M} T + δ ) .$$

A reference point of the third time range c is the start time of the first signal. Refer to related descriptions of the first time range. Details are not described herein again.

Optionally, a value of c may alternatively be 0, 1, . . . , or C−1, and the c^{th} segment of sub-signal is a signal of the third signal within the third time range c. The third time range c may be one of the following:

$$[ \frac{M + c - 1}{M} T + δ , \frac{M + c}{M} T + δ ] , ( \frac{M + c - 1}{M} T + δ , \frac{M + c}{M} T + δ ] , [ \text{} \frac{M + c - 1}{M} T + δ , \frac{M + c}{M} T + δ ) , \text{} or ( \frac{M + c - 1}{M} T + δ , \frac{M + c}{M} T + δ ) .$$

Parts related to c in texts and formulas in the subsequent embodiments may be adaptively adjusted accordingly. In the following embodiments, an example in which c=1, 2, . . . , or C is used for description.

In a possible embodiment, a sampling frequency for the c^{th} segment of sampling of the third signal is greater than or equal to NΔf_{C}/C; or a sampling frequency for the c^{th} segment of sampling of the third signal may be greater than or equal to B/C. N is greater than or equal to the quantity of subcarriers included in the bandwidth of the first signal, and N is a positive integer. Δf_{C} is a bandwidth of the subcarrier, or a subcarrier spacing. B is the bandwidth of the first signal.

Optionally,

$$\frac{N}{C M} - point$$

sampling may be performed on the c^{th} segment of sub-signal of the third signal within the third time range c. In other words, a sampling result obtained by sampling the c^{th} segment of sub-signal of the third signal within the third time range c includes signals at

$$\frac{N}{C M}$$

sampling points.

In a possible embodiment, sampling positions of any two sub-signals in the C segments of sub-signals of the third signal are different. For example,

$$\frac{N}{M} = 10$$

and C=2. 10 points originally may be sampled for the third signal within the first time range. A sampling position of a 1^{st} segment of sub-signal of the third signal within the third time range may correspond to 1^{st}, 2^{nd}, 3^{rd}, 4^{th}, and 5^{th} sampling points of the third signal within the first time range, and a sampling position of a 2^{nd} segment of sub-signal of the third signal within the third time range may correspond to 6^{th}, 7^{th}, 8^{th}, 9^{th}, and 10^{th} sampling points of the third signal within the first time range. For details, refer to the related descriptions of “the sampling positions of any two delayed signals in the A delayed signals of the third signal are different”.

### (b) Determine the Target Signal Based on Sampling Results of the C Segments of Sampling.

Optionally, the sampling results of the C segments of sampling may be re-sorted to obtain the first time domain sequence. For example, the sampling results of the C segments of sampling may be sequentially arranged from front to back according to a time domain order of sampling points that are of the third signal within the first time range and that correspond to sampling points within the third time range, to obtain the first time domain sequence. For details, refer to related descriptions of “re-sorting the sampling results of the A delayed signals of the third signal to obtain the first time domain sequence”.

In a possible embodiment, when the target signal is the discrete time domain signal or the discrete time domain sequence corresponding to the target signal, the first time domain sequence is the discrete time domain signal or the discrete time domain sequence corresponding to the target signal.

In another possible embodiment, when the target signal is the discrete frequency domain signal or the discrete frequency domain sequence corresponding to the target signal, the receiving device may perform N/M-point DFT on the first time domain sequence to obtain the discrete frequency domain signal or the discrete frequency domain sequence corresponding to the target signal.

Based on the possible embodiment, the sampling frequency and the quantity of DFT points can also be reduced, so that capability requirements and costs for the ADC and the DFT module are reduced.

In a possible embodiment, functions related to step or operation S401 and step or operation S402 may be implemented on a radio frequency, and functions related to step or operation S403 to step or operation S405 may be implemented on a baseband (for example, by using a baseband chip).

In this embodiment, a method for dividing an input signal into a plurality of signals and then delaying some of the signals is mentioned a plurality of times. For example, the second signal is delayed K times (as shown in FIG. 6), or the input signal of the i^{th}-stage circuit in the X-stage circuit is delayed (as shown in FIG. 7 and FIG. 8). In some systems, a step or operation of dividing a signal into a plurality of signals reduces amplitude or energy of the plurality of signals in comparison with the original signal. However, because amplitude or energy of each signal is an equal fraction of amplitude or energy of the source signal, receiving performance of a receiver is not affected. In addition, after the signal is divided into the plurality of signals, the plurality of signals may be amplified by using some amplifiers, so that average energy or amplitude of the plurality of signals is consistent with that of the original signal. Therefore, the foregoing amplitude or energy reduction is not considered in related mathematical expressions in the embodiments, but the essence of the present embodiment is not affected.

It may be understood that, in embodiments, the receiving device may perform some or all of the steps or operations in embodiments. These steps or operations are examples. In embodiments, other steps or operations or variations of the steps or operations may be further performed. In addition, the steps or operations may be performed in an order different from an order presented in embodiments, and not all of the steps or operations in embodiments may be performed. For example, when the receiving device has only a radio frequency processing function or only a baseband processing function, the receiving device may perform only some steps or operations that are performed by the receiving device and that are described in embodiments. For example, when the receiving device has only the radio frequency processing function, only step or operation S401 and step or operation S402 are performed; and when the receiving device has only the baseband processing function, only step or operation S403 to step or operation S405 are performed, and other operations may be performed by at least one other device.

It may be understood that, in the foregoing embodiments, the methods and/or steps or operations implemented by the receiving device may be alternatively implemented by a component (for example, a processor, a chip, a chip system, a circuit, a logical module, or software) that may be used in the receiving device. The chip system may include a chip, or the chip system may include a chip and another discrete device.

It may be understood that, to implement the foregoing functions, the communication apparatus or the sensing apparatus includes corresponding hardware structures and/or software modules for performing the functions. A person skilled in the art may easily be aware that, in combination with units and algorithm steps or operations of the examples described in embodiments, the embodiments may be implemented by hardware or a combination of hardware and computer software. Whether a function is performed by hardware or hardware driven by computer software depends on particular applications and design constraints of the solutions. A person skilled in the art may use different methods to implement the described functions for each particular application, but it may not be considered that the implementation goes beyond the scope of the embodiments.

In embodiments, the communication apparatus or the sensing apparatus may be divided into functional modules based on the foregoing method embodiments. For example, functional modules may be obtained through division based on corresponding functions, or two or more functions may be integrated into one processing module. The integrated module may be implemented in a form of hardware, or may be implemented in a form of a software functional module. It may be noted that, in embodiments, module division is an example, and is a logical function division. In some embodiments, another division manner may be used.

FIG. 11 is a diagram of a structure of a communication apparatus or sensing apparatus 110. The apparatus 110 includes a processing module 1101 and a transceiver module 1102. The apparatus 110 may be configured to implement a function of the foregoing receiving device.

In some embodiments, the communication apparatus 110 may further include a storage module (not shown in FIG. 11), configured to store program instructions and data.

In some embodiments, the transceiver module 1102 may also be referred to as a transceiver unit, and is configured to implement a sending function and/or a receiving function. The transceiver module 1102 may include a transceiver circuit, a transceiver machine, a transceiver, or a communication interface.

In some embodiments, the transceiver module 1102 may include a receiving module and a sending module, respectively configured to perform receiving steps or operations and sending steps or operations performed by the receiving device in the foregoing method embodiments, and/or configured to support other processes of the technologies. The processing module 1101 may be configured to perform processing (for example, determining) steps or operations performed by the receiving device in the foregoing method embodiments, and/or configured to support other processes of the technologies.

The transceiver module 1102 is configured to receive a first signal, where the first signal includes a target signal, the target signal occupies one subcarrier in every M consecutive subcarriers, and M is a positive integer greater than 1. The processing module 1101 is configured to perform down-conversion on the first signal to obtain a second signal. The processing module 1101 is further configured to determine a third signal based on the second signal, where the third signal includes superposition of K delayed signals of the second signal, and delay time associated with a k^{th} delayed signal in the K delayed signals is

$$\frac{( k - 1 ) T}{K} + δ ,$$

where T is a time length of the first signal, k=1, 2, . . . , or K, δ is greater than or equal to 0, and K is a positive integer greater than or equal to M. The processing module 1101 is further configured to sample the third signal to determine the target signal.

Optionally, that the processing module 1101 is further configured to determine the third signal based on the second signal includes: the processing module 1101 is further configured to delay the second signal K times to obtain the K delayed signals of the second signal, where the delay time associated with the k^{th} delayed signal is

$$\frac{( k - 1 ) T}{K} + δ ;$$

and the processing module 1101 is further configured to superpose the K delayed signals to obtain the third signal.

Optionally, that the processing module 1101 is further configured to determine the third signal based on the second signal includes: the processing module 1101 is further configured to determine the third signal by using an X-stage circuit, wherein the X-stage circuit, an output signal of an i^{th}-stage circuit is a signal obtained by superposing an input signal of the i^{th}-stage circuit and a signal obtained by delaying the input signal of the i^{th}-stage circuit, where i=1, 2, . . . , or X, and X is a positive integer greater than 1. When i=1, the input signal of the i^{th}-stage circuit is a signal obtained by delaying the second signal by δ, or when i>1, the input signal of the i^{th}-stage circuit is an output signal of an (i−1)^{th}-stage circuit, the third signal is an output signal of an X^{th}-stage circuit, and the output signal of the X^{th}-stage circuit includes superposition of the K delayed signals of the second signal.

Optionally, when K=M, that the processing module 1101 is further configured to sample the third signal includes: the processing module 1101 is further configured to sample the third signal within a time range of

$$[ \frac{M - 1}{M} T + δ , T + δ ] ,$$

where a reference point of the time range is start time of the first signal.

Optionally, when K=M, that the processing module 1101 is further configured to sample the third signal includes: the processing module 1101 is further configured to delay the third signal for A times to obtain A delayed signals of the third signal, where A is a positive integer, delay time associated with an a^{th} delayed signal is

$$\frac{( a - 1 ) T}{M} + {δ}_{a} ,$$

δₐ is greater than or equal to 0, and a=1, 2, . . . , or A; and the processing module 1101 is further configured to sample the a^{th} delayed signal of the third signal within a time range of

$$[ \frac{M + a - 2}{M} T + δ + {\sum }_{j = 1}^{a} {δ}_{j} , \frac{M + a - 1}{M} T + δ + {\sum }_{j = 1}^{a} {δ}_{j} ] ,$$

where a reference point of the time range is start time of the first signal.

Optionally, K=M−1+C, and when C is a positive integer, that the processing module 1101 is further configured to sample the third signal includes: the processing module 1101 is further configured to perform C segments of sampling on the third signal. A c^{th} segment of sampling corresponds to a signal of the third signal within a time range c, c=1, 2, . . . , or C, and the time range c is

$$[ \frac{M + c - 2}{M} T + δ , \frac{M + c - 1}{M} T + δ ] .$$

A reference point of the time range c is start time of the first signal.

Optionally, that the processing module 1101 is further configured to sample the third signal to determine the target signal includes: the processing module 1101 is configured to sample the third signal to obtain a first time domain sequence, and is further configured to perform N/M-point discrete Fourier transform DFT on the first time domain sequence to obtain a frequency domain signal corresponding to the target signal, where N is greater than or equal to a quantity of subcarriers included in a bandwidth of the first signal, and N is a positive integer.

In a possible embodiment, the functions/actions implemented by the processing module 1101 may alternatively be implemented by the transceiver module 1102.

All related content of the steps or operations in the foregoing method embodiments may be cited in function descriptions of the corresponding functional modules. Details are not described herein again.

In the embodiments, the communication apparatus or sensing apparatus 110 may be presented in a form of functional modules obtained through division in an integrated manner. The “module” herein may be an application-specific integrated circuit (ASIC), a circuit, a processor that executes one or more software or firmware programs, a memory, an integrated logic circuit, and/or another component that can provide the foregoing functions.

In some embodiments, when the communication apparatus or sensing apparatus 110 in FIG. 11 is a chip or a chip system, a function/an implementation process of the transceiver module 1102 may be implemented through an input/output interface (or a communication interface) of the chip or the chip system, and a function/an implementation process of the processing module 1101 may be implemented by a processor (or a processing circuit) of the chip or the chip system.

Because the communication apparatus or sensing apparatus 110 provided in this embodiment may perform the foregoing methods, for an effect that can be achieved by the communication apparatus or sensing apparatus 110, refer at least to the foregoing method embodiments. Details are not described herein again.

FIG. 12 is a diagram of a structure of another communication apparatus or sensing apparatus 120. The apparatus 120 may be configured to implement a function of the foregoing receiving device. The apparatus 120 includes a first circuit 1201.

Optionally, the apparatus 120 may further include at least one of the following: an antenna 1202, a frequency mixer 1203, an analog-to-digital converter 1204, a DFT module 1205, and a second circuit (not shown in FIG. 12).

The first circuit is configured to determine a third signal based on a second signal, where the second signal is a signal obtained by performing down-conversion on a first signal. The first signal includes a target signal, the target signal occupies one subcarrier in every M consecutive subcarriers, and M is a positive integer greater than 1. The third signal is an input signal of the analog-to-digital converter. The third signal includes superposition of K delayed signals of the second signal, and delay time associated with a k^{th} delayed signal in the K delayed signals is

$$\frac{( k - 1 ) T}{K} + δ ,$$

where T is a time length of the first signal, k=1, 2, . . . , or K, δ is greater than or equal to 0, and K is a positive integer greater than or equal to M.

Optionally, the antenna 1202 is configured to receive the first signal. The first signal includes the target signal, and the target signal occupies one subcarrier in every M consecutive subcarriers.

Optionally, the frequency mixer 1203 is configured to perform down-conversion on the first signal to obtain the second signal.

Optionally, the analog-to-digital converter 1204 is configured to sample the third signal to obtain a first time domain sequence. The DFT module 1205 is configured to determine the target signal based on the first time domain sequence.

In a possible embodiment, the first circuit includes K delayers and one adder. A k^{th} delayer in the K delayers is configured to delay the second signal by

$$\frac{( k - 1 ) T}{K} + δ$$

to obtain the k^{th} delayed signal of the second signal. The adder is configured to superpose the K delayed signals of the second signal to obtain the third signal. For example, the adder is a K-input adder.

In a possible embodiment, the first circuit includes K−1 delayers and one adder. A k^{th} (k=1, 2, . . . , or K−1) delayer in the K−1 delayers is configured to delay the second signal by

$$\frac{kT}{K} + δ$$

to obtain the k^{th} delayed signal of the second signal. The adder is configured to superpose the second signal and K−1 delayed signals of the second signal to obtain the third signal. For example, the adder is a K-input adder.

In another possible embodiment, the first circuit includes an X-stage circuit, and in the X-stage circuit, an output signal of an i^{th}-stage circuit is a signal obtained by superposing an input signal of the i^{th}-stage circuit and a signal obtained by delaying the input signal of the i^{th}-stage circuit, where i=1, 2, . . . , or X, and X is a positive integer greater than 1. When i=1, the input signal of the i^{th}-stage circuit is a signal obtained by delaying the second signal by δ, or when i>1, the input signal of the i^{th}-stage circuit is an output signal of an (i−1)^{th}-stage circuit, the third signal is an output signal of an X^{th}-stage circuit, and the output signal of the X^{th}-stage circuit includes superposition of the K delayed signals of the second signal.

In a possible example, when K=2^{X}, the i^{th}-stage circuit includes one delayer and one adder. The delayer is configured to delay the input signal of the i^{th}-stage circuit by

$$\frac{T}{{2}^{i}} .$$

The adder is configured to superpose the input signal of the i^{th}-stage circuit and an output signal of the delayer in the i^{th}-stage circuit. For example, the adder is a two-input adder.

In another possible example, when

$$K = {\prod }_{i = 1}^{X} {K}_{i} ,$$

the i^{th}-stage circuit includes Kᵢ−1 delayers and one adder. The Kᵢ−1 delayers are respectively configured to delay the input signal of the i^{th}-stage circuit by

$$\frac{T}{{\prod }_{j = 1}^{i} {K}_{j}} , \frac{2 T}{{\prod }_{j = 1}^{i} {K}_{j}} , ... , \frac{( {K}_{i} - 1 ) T}{{\prod }_{j = 1}^{i} {K}_{j}} .$$

The adder is configured to superpose the input signal of the i^{th}-stage circuit and output signals of the Kᵢ−1 delayers in the i^{th}-stage circuit. For example, the adder is a Kᵢ-input adder.

Optionally, when K=M, the analog-to-digital converter 1204 is configured to sample the third signal within a time range of

$$[ \frac{M - 1}{M} T + δ , T + δ ] ,$$

where a reference point of the time range is start time of the first signal.

Optionally, when K=M, the second circuit is configured to delay the third signal A times to obtain A delayed signals of the third signal, where A is a positive integer, delay time associated with an a^{th} delayed signal is

$$\frac{( a - 1 ) T}{M} + {δ}_{a} ,$$

δₐ is greater than or equal to 0, and a=1, 2, . . . , or A. The analog-to-digital converter 1204 is configured to sample the a^{th} delayed signal of the third signal within a time range of

$$[ \frac{M + a - 2}{M} T + δ {\sum }_{j = 1}^{a} {δ}_{j} , \frac{M + a - 1}{M} T + δ + {\sum }_{j = 1}^{a} {δ}_{j} ] ,$$

where a reference point of the time range is start time of the first signal.

For example, the second circuit includes A delayers, and the A delayers are separately configured to delay the third signal by

$$\frac{( a - 1 ) T}{M} + {δ}_{a} .$$

The communication apparatus or the sensing apparatus may further include a selector. The selector is configured to be connected to an a^{th} delayer within the time range of

$$[ \frac{M + a - 2}{M} T + δ + {\sum }_{j = 1}^{a} {δ}_{j} , \frac{M + a - 1}{M} T + δ + {\sum }_{j = 1}^{a} {δ}_{j} ] ,$$

so that the analog-to-digital converter 1204 samples the a^{th} delayed signal of the third signal within the time range of

$$[ \frac{M + a - 2}{M} T + δ + {\sum }_{j = 1}^{a} {δ}_{j} , \frac{M + a - 1}{M} T + δ + {\sum }_{j = 1}^{a} {δ}_{j} ] .$$

Optionally, when K=M−1+B, and B is a positive integer, the analog-to-digital converter 1204 is configured to perform C segments of sampling on the third signal. A c^{th} segment of sampling corresponds to a signal of the third signal within a time range c, c=1, 2, . . . , or C, and the time range c is

$$[ \frac{M + c - 2}{M} T + δ , \frac{M + c - 1}{M} T + δ ] .$$

A reference point of the time range c is start time of the first signal.

Optionally, the DFT module 1205 is configured to perform N/M-point discrete Fourier transform DFT on the first time domain sequence to obtain a frequency domain signal corresponding to the target signal, where N is greater than or equal to a quantity of subcarriers included in a bandwidth of the first signal, and N is a positive integer.

All related content of the steps or operations in the foregoing method embodiments may be cited in function descriptions of the corresponding circuits, components, or functional modules. Details are not described herein again.

In a possible product form, the receiving device in embodiments may be further implemented by using one or more field programmable gate arrays (FPGA), a programmable logic device (PLD), a controller, a state machine, gate logic, a discrete hardware component, any other suitable circuit, or any combination of circuits that can perform various functions described throughout the embodiments.

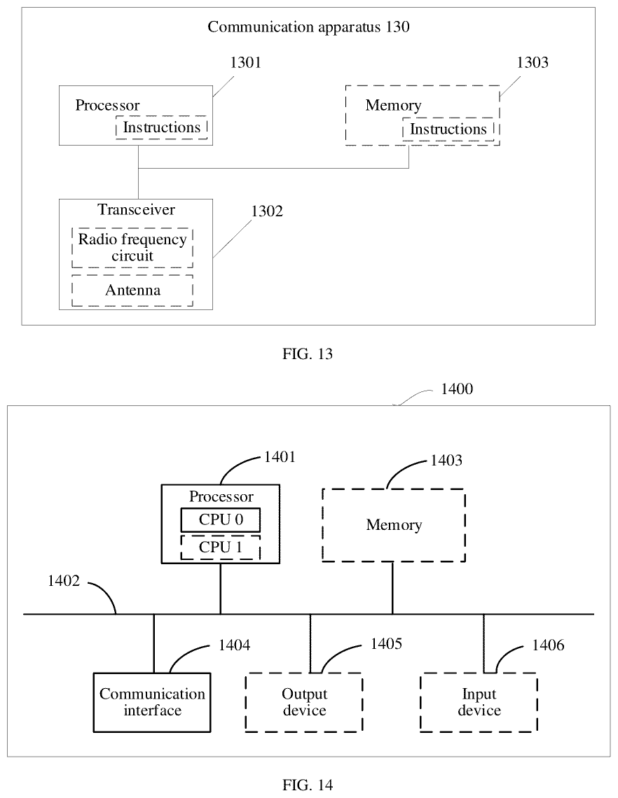

In another possible product form, the receiving device in embodiments may be implemented by a general bus architecture. For ease of description, FIG. 13 is a diagram of a structure of a communication apparatus or sensing apparatus 130 according to an embodiment. The apparatus 130 includes a processor 1301 and a transceiver 1302. The apparatus 130 may be a receiving device, or a chip or chip system in the receiving device. FIG. 13 shows only main components of the apparatus 130. In addition to the processor 1301 and the transceiver 1302, the apparatus may further include a memory 1303 and an input/output apparatus (not shown in the figure).

Optionally, the processor 1301 is configured to process a communication protocol and communication data, control the entire communication apparatus or sensing apparatus, execute a software program, and process data of the software program. The memory 1303 is configured to store a software program and data. The transceiver 1302 may include a radio frequency circuit and an antenna. The radio frequency circuit is configured to perform conversion between a baseband signal and a radio frequency signal, and process the radio frequency signal. The antenna is configured to receive and send radio frequency signals in a form of an electromagnetic wave. The input/output apparatus, for example, a touchscreen, a display, or a keyboard, is configured to receive data input by a user and output data to the user.

Optionally, the processor 1301, the transceiver 1302, and the memory 1303 may be connected through a communication bus.

After the communication apparatus or sensing apparatus is powered on, the processor 1301 may read the software program in the memory 1303, interpret and execute instructions of the software program, and process data of the software program. When data may be sent wirelessly, the processor 1301 performs baseband processing on the to-be-sent data, and then outputs a baseband signal to the radio frequency circuit. The radio frequency circuit performs radio frequency processing on the baseband signal, and then sends the radio frequency signal in an electromagnetic wave form through the antenna. When data is sent to the communication apparatus or sensing apparatus, the radio frequency circuit receives a radio frequency signal through the antenna, converts the radio frequency signal into a baseband signal, and outputs the baseband signal to the processor 1301. The processor 1301 converts the baseband signal into data, and processes the data.

In another embodiment, the radio frequency circuit and the antenna may be disposed independently of the processor that performs baseband processing. For example, in a distributed scenario, the radio frequency circuit and the antenna may be remotely disposed independently of the communication apparatus or sensing apparatus.

In some embodiments, in terms of hardware implementation, a person skilled in the art may figure out that the apparatus 110 may be in a form of the apparatus 130 shown in FIG. 13.

In an example, the functions or implementation processes of the processing module 1101 in FIG. 11 may be implemented by the processor 1301 in the apparatus 130 shown in FIG. 13 by invoking computer-executable instructions stored in the memory 1303. The functions or implementation processes of the transceiver module 1102 in FIG. 11 may be implemented by the transceiver 1302 in the apparatus 130 shown in FIG. 13.

In another possible product form, the receiving device in the embodiments may use a composition structure shown in FIG. 14, or include components shown in FIG. 14. FIG. 14 is a composition diagram of a communication apparatus or sensing apparatus 1400 according to the embodiments. The apparatus 1400 may be a receiving device or a chip or system on chip in the receiving device.

As shown in FIG. 14, the apparatus 1400 includes at least one processor 1401 and at least one communication interface (in FIG. 14, only an example in which one communication interface 1404 and one processor 1401 are included is used for description). Optionally, the apparatus 1400 may further include a communication bus 1402 and a memory 1403.

The processor 1401 may be a general-purpose central processing unit (CPU), a general-purpose processor, a network processor (NP), a digital signal processor (DSP), a microprocessor, a microcontroller, a programmable logic device (PLD), or any combination thereof. Alternatively, the processor 1401 may be another apparatus having a processing function, for example, a circuit, a device, or a software module. This is not limited.

The communication bus 1402 is configured to connect different components of the communication apparatus or sensing apparatus 1400, so that the different components can communicate with each other. The communication bus 1402 may be a peripheral component interconnect (PCI) bus, an extended industry standard architecture (EISA) bus, or the like. The bus may include an address bus, a data bus, a control bus, and the like. For ease of representation, only one bold line is used in FIG. 14 for representation, but this does not mean that there is only one bus or only one type of bus.

The communication interface 1404 is configured to communicate with another device or communication network. For example, the communication interface 1404 may be a module, a circuit, a transceiver, or any apparatus that can implement communication. Optionally, the communication interface 1404 may alternatively be an input/output interface located in the processor 1401, to implement signal input and signal output of the processor.

The memory 1403 may be an apparatus having a storage function, and is configured to store instructions and/or data. The instructions may be computer programs.

For example, the memory 1403 may be a read-only memory (ROM) or another type of static storage device that can store static information and/or instructions, may be a random access memory (RAM) or another type of dynamic storage device that can store information and/or instructions, or may be an electrically erasable programmable read-only memory (EEPROM), a compact disc read-only memory (CD-ROM) or another compact disc storage, an optical disc storage (including a compact disc, a laser disc, an optical disc, a digital versatile disc, a Blu-ray disc, and the like), or a magnetic disk storage medium or another magnetic storage device. This is not limited.

It should be noted that the memory 1403 may be independent of the processor 1401, or may be integrated with the processor 1401. The memory 1403 may be located in the communication apparatus or sensing apparatus 1400, or may be located outside the communication apparatus or sensing apparatus 1400. This is not limited. The processor 1401 is configured to execute the instructions stored in the memory 1403, to implement the methods provided in the following embodiments.

In an optional embodiment, the communication apparatus or sensing apparatus 1400 may further include an output device 1405 and an input device 1406. The output device 1405 communicates with the processor 1401, and may display information in a plurality of manners. For example, the output device 1405 may be a liquid crystal display (LCD), a light emitting diode (LED) display device, a cathode ray tube (CRT) display device, or a projector. The input device 1406 communicates with the processor 1401, and may receive an input of a user in a plurality of manners. For example, the input device 1406 may be a mouse, a keyboard, a touchscreen device, or a sensor device.

In some embodiments, in terms of hardware implementation, a person skilled in the art may figure out that the apparatus 110 shown in FIG. 11 may be in a form of the apparatus 1400 shown in FIG. 14.

In an example, the functions or implementation processes of the processing module 1101 in FIG. 11 may be implemented by the processor 1401 in the apparatus 1400 shown in FIG. 14 by invoking computer-executable instructions stored in the memory 1403. The functions or implementation processes of the transceiver module 1102 in FIG. 11 may be implemented by the communication interface 1404 in the apparatus 1400 shown in FIG. 14.

It may be noted that the structure shown in FIG. 14 does not constitute a limitation on the receiving device. For example, in some other embodiments, the receiving device may include more or fewer components than those shown in the figure, combine some of the components, split some of the components, or have different layouts of the components. The components shown in the figure may be implemented by hardware, software, or a combination of software and hardware.

In some embodiments, an embodiment further provides a communication apparatus or sensing apparatus. The apparatus includes a processor, configured to implement the method in any one of the foregoing method embodiments.

In a possible embodiment, the communication apparatus or sensing apparatus further includes a memory. The memory is configured to store a computer program and data. The computer program may include instructions. The processor may invoke instructions in the computer program stored in the memory, to instruct the communication apparatus or sensing apparatus to perform the method in any one of the foregoing method embodiments. In another embodiment, the memory may not be in the communication apparatus or sensing apparatus.

In another possible embodiment, the communication apparatus or sensing apparatus further includes an interface circuit. The interface circuit is a code/data read/write interface circuit, and the interface circuit is configured to receive computer-executable instructions (where the computer-executable instructions are stored in the memory, and may be directly read from the memory, or may be read via another component) and send the computer-executable instructions to the processor.

In still another possible embodiment, the communication apparatus or sensing apparatus further includes a communication interface, and the communication interface is configured to communicate with a module outside the communication apparatus or sensing apparatus.

It may be understood that the communication apparatus or sensing apparatus may be a chip or a chip system. When the communication apparatus or sensing apparatus is a chip system, the communication apparatus or sensing apparatus may include a chip, or may include a chip and another discrete device. This is not limited.

The embodiments further provide a non-transitory computer-readable storage medium. The non-transitory computer-readable storage medium stores a computer program or instructions. When the computer program or the instructions are executed by a computer, functions in any one of the foregoing method embodiments are implemented.

The embodiments further provide a computer program product. When the computer program product is executed by a computer, functions in any one of the foregoing method embodiments are implemented.

A person of ordinary skill in the art may understand that, for the purpose of convenient and brief description, for a detailed working process of the foregoing system, apparatuses, and units, refer to a corresponding process in the foregoing method embodiments. Details are not described herein again.

It may be understood that the system, apparatus, and method described in the embodiments may alternatively be implemented in another manner. For example, the described apparatus embodiments are examples. For example, division into the units is logical function division and may be other division in some embodiments. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or the units may be implemented in electronic, mechanical, or other forms.

The units described as separate parts may or may not be physically separate, and may be located in one position, or may be distributed on a plurality of network units. Parts displayed as units may be or may not be physical units. Some or all of the units may be selected based on requirements to achieve the objectives of the solutions of embodiments.

In addition, functional units in embodiments may be integrated into one processing unit, or each of the units may exist alone physically, or two or more units may be integrated into one unit.

All or some of the foregoing embodiments may be implemented by using software, hardware, firmware, or any combination thereof. When a software program is used to implement embodiments, embodiments may be implemented completely or partially in a form of a computer program product. The computer program product includes one or more computer instructions. When the computer program instructions are loaded and executed on the computer, the procedure or functions according to embodiments are all or partially generated. The computer may be a general-purpose computer, a dedicated computer, a computer network, or other programmable apparatuses. The computer instructions may be stored in a non-transitory computer-readable storage medium or may be transmitted from a non-transitory computer-readable storage medium to another non-transitory computer-readable storage medium. For example, the computer instructions may be transmitted from a website, computer, server, or data center to another website, computer, server, or data center in a wired (for example, a coaxial cable, an optical fiber, or a digital subscriber line (DSL)) or wireless (for example, infrared, radio, or microwave) manner. The non-transitory computer-readable storage medium may be any usable medium accessible by the computer, or a data storage device, for example, a server or a data center, integrating one or more usable media. The usable medium may be a magnetic medium (for example, a floppy disk, a hard disk drive, or a magnetic tape), an optical medium (for example, a DVD), a semiconductor medium (for example, a solid-state drive (SSD)), or the like. In embodiments, the computer may include the foregoing apparatuses.

Although the embodiments are described with reference to the accompanying drawings, in implementing the embodiments, a person skilled in the art may understand and implement variations of the embodiments by viewing the accompanying drawings, and embodiments. Herein, “comprising” does not exclude additional component(s), step(s), or operation(s), and “a” or “one” does not exclude plurality. A single processor or other unit may implement several functions enumerated in the embodiments. Some measures are recited in the embodiments that are different from each other, but this does not mean that these measures cannot be combined to achieve a better effect.

Although the embodiments are described with reference to features and embodiments thereof, various modifications and combinations may be made without departing from the spirit and scope of the embodiments. Accompanying drawings are provided by way of example and are not intended to limit the scope of the embodiments. It is clear that a person skilled in the art can make various modifications and variations to the embodiments without departing from the spirit and scope of the embodiments. The embodiments are intended to cover these modifications and variations.

1. A method, comprising:
receiving a first signal, wherein the first signal comprises a target signal, the target signal occupies one subcarrier in every M consecutive subcarriers, and M is a positive integer greater than 1;
performing a down-conversion on the first signal to obtain a second signal;
determining a third signal based on the second signal, wherein the third signal comprises superposition of K delayed signals of the second signal, and a delay time associated with a k^{th} delayed signal in the K delayed signals is
$$\frac{( k - 1 ) T}{K} + δ ,$$
wherein T is a time length of the first signal, k=1, 2, . . . , or K, δ is greater than or equal to 0, and K is a positive integer greater than or equal to M; and
sampling the third signal to determine the target signal.

2. The method according to claim 1, wherein a frequency of the down-conversion is related to at least one of a carrier frequency of the first signal and a position of the target signal.

3. The method according to claim 1, wherein determining the third signal based on the second signal comprises:
delaying the second signal K times to obtain the K delayed signals of the second signal, wherein the delay time associated with the k^{th} delayed signal is
$$\frac{( k - 1 ) T}{K} + δ ;$$
and
superposing the K delayed signals to obtain the third signal.

4. The method according to claim 1, wherein determining the third signal based on the second signal comprises: determining the third signal by using an X-stage circuit, wherein in the X-stage circuit,
an output signal of an i^{th}-stage circuit is a signal obtained by superposing an input signal of the i^{th}-stage circuit and a signal obtained by delaying the input signal of the i^{th}-stage circuit, wherein i=1, 2, . . . , or X, and X is a positive integer greater than 1; and
when i=1, the input signal of the i^{th}-stage circuit is a signal obtained by delaying the second signal by δ, or when i>1, the input signal of the i^{th}-stage circuit is an output signal of an (i−1)^{th}-stage circuit, the third signal is an output signal of an X^{th}-stage circuit, and the output signal of the X^{th}-stage circuit comprises superposition of the K delayed signals of the second signal.

5. The method according to claim 4, wherein K=2^{X}, and
the output signal of the i^{th}-stage circuit is a signal obtained by superposing the input signal of the i^{th}-stage circuit and a signal obtained by delaying the input signal of the i^{th}-stage circuit by
$$\frac{T}{{2}^{i}} .$$

6. The method according to claim 4, wherein
$$K = {Π}_{i = 1}^{X} {K}_{i} ,$$
and
the output signal of the i^{th}-stage circuit is a signal obtained by superposing the input signal of the i^{th}-stage circuit and signals obtained by respectively delaying the input signal of the i^{th}-stage circuit by
$$\frac{T}{{Π}_{j = 1}^{i} {K}_{j}} , \frac{2 T}{{Π}_{j = 1}^{i} {K}_{j}} , … , and \frac{( {K}_{i} - 1 ) T}{{Π}_{j = 1}^{i} {K}_{j}} ,$$
wherein Π represents cumulative multiplication, and Kᵢ is a positive integer.

7. The method according to claim 1, wherein K=M, and sampling the third signal comprises:
sampling the third signal within a time range of
$$[ \frac{M - 1}{M} T + δ , T + δ ] ,$$
wherein a reference point of the time range is start time of the first signal.

8. The method according to claim 1, wherein K=M, and sampling the third signal comprises:
delaying the third signal A times to obtain A delayed signals of the third signal, wherein A is a positive integer, delay time associated with an a^{th} delayed signal is
$$\frac{( a - 1 ) T}{M} + {δ}_{a} ,$$
δₐ is greater than or equal to 0, and a=1, 2, . . . , or A; and
sampling the a^{th} delayed signal of the third signal within a time range of
$$[ \frac{M + a - 2}{M} T + δ + {\sum }_{j = 1}^{a} {δ}_{j} , \frac{M + a - 1}{M} T + δ + {\sum }_{j = 1}^{a} {δ}_{j} ] ,$$
wherein a reference point of the time range is start time of the first signal.

9. The method according to claim 8, wherein a sampling frequency used for sampling the a^{th} delayed signal of the third signal is greater than or equal to NΔf_{C}/A, wherein N is greater than or equal to a quantity of subcarriers comprised in a bandwidth of the first signal, N is a positive integer, and Δf_{C} is a bandwidth of the subcarrier.

10. The method according to claim 8, wherein sampling positions of any two delayed signals in the A delayed signals of the third signal are different.

11. An apparatus, comprising a first circuit, wherein
the first circuit is configured to determine a third signal based on a second signal, wherein the third signal comprises superposition of K delayed signals of the second signal, and delay time associated with a k^{th} delayed signal in the K delayed signals is
$$\frac{( k - 1 ) T}{K} + δ ;$$
the second signal is a signal obtained by performing a down-conversion on a first signal, the first signal comprises a target signal, the target signal occupies one subcarrier in every M consecutive subcarriers, M is a positive integer greater than 1, T is a time length of the first signal, k=1, 2, . . . , or K, δ is greater than or equal to 0, and K is a positive integer greater than or equal to M; and the third signal is an input signal of an analog-to-digital converter.

12. The apparatus according to claim 11, wherein the first circuit comprises K delayers and one adder, wherein
a k^{th} delayer in the K delayers is configured to delay the second signal by
$$\frac{( k - 1 ) T}{K} + δ$$
to obtain the k^{th} delayed signal of the second signal; and
the adder is configured to superpose the K delayed signals of the second signal to obtain the third signal.

13. The apparatus according to claim 11, wherein the first circuit comprises an X-stage circuit, and in the X-stage circuit,
an output signal of an i^{th}-stage circuit is a signal obtained by superposing an input signal of the i^{th}-stage circuit and a signal obtained by delaying the input signal of the i^{th}-stage circuit, wherein i=1, 2, . . . , or X, and X is a positive integer greater than 1; and
when i=1, the input signal of the i^{th}-stage circuit is a signal obtained by delaying the second signal by δ, or when i>1, the input signal of the i^{th}-stage circuit is an output signal of an (i−1)^{th}-stage circuit, the third signal is an output signal of an X^{th}-stage circuit, and the output signal of the X^{th}-stage circuit comprises superposition of the K delayed signals of the second signal.

14. The apparatus according to claim 13, wherein K=2^{X}, and the i^{th}-stage circuit comprises one delayer and one adder, wherein
the delayer is configured to delay the input signal of the i^{th}-stage circuit by
$$\frac{T}{{2}^{i}} ;$$
and
the adder is configured to superpose the input signal of the i^{th}-stage circuit and an output signal of the delayer in the i^{th}-stage circuit.

15. The apparatus according to claim 13, wherein
$$K = {Π}_{i = 1}^{X} {K}_{i} ,$$
and the i^{th}-stage circuit comprises Kᵢ−1 delayers and one adder, wherein
the Kᵢ−1 delayers are respectively configured to delay the input signal of the i^{th}-stage circuit by
$$\frac{T}{{Π}_{j = 1}^{i} {K}_{j}} , \frac{2 T}{{Π}_{j = 1}^{i} {K}_{j}} , … , and \frac{( {K}_{i} - 1 ) T}{{Π}_{j = 1}^{i} {K}_{j}} ;$$
and
the adder is configured to superpose the input signal of the i^{th}-stage circuit and output signals of the Kᵢ−1 delayers in the i^{th}-stage circuit.

16. The apparatus according to claim 11, wherein K=M, and the apparatus further comprises the analog-to-digital converter, wherein
the analog-to-digital converter is configured to sample the third signal within a time range of
$$[ \frac{M - 1}{M} T + δ , T + δ ] ,$$
wherein a reference point of the time range is start time of the first signal.

17. The apparatus according to claim 11, wherein K=M, and the apparatus further comprises the analog-to-digital converter and a second circuit, wherein
the second circuit is configured to delay the third signal A times to obtain A delayed signals of the third signal, wherein A is a positive integer, delay time associated with an a^{th} delayed signal is
$$\frac{( a - 1 ) T}{M} + {δ}_{a} ,$$
δₐ is greater than or equal to 0, and a=1, 2, . . . , or A; and
the analog-to-digital converter is configured to sample the a^{th} delayed signal of the third signal within a time range of
$$[ \frac{M + a - 2}{M} T + δ + {Σ}_{j = 1}^{a} {δ}_{j} , \frac{M + a - 1}{M} T + δ + {Σ}_{j = 1}^{a} {δ}_{j} ] ,$$
wherein a reference point of the time range is start time of the first signal.

18. The apparatus according to claim 17, wherein a sampling frequency used for sampling the a^{th} delayed signal of the third signal is greater than or equal to NΔf_{C}/A, wherein N is greater than or equal to a quantity of subcarriers comprised in a bandwidth of the first signal, N is a positive integer, and Δf_{C} is a bandwidth of the subcarrier.

19. The apparatus according to claim 17, wherein sampling positions of any two delayed signals in the A delayed signals of the third signal are different.

20. The apparatus according to claim 11, wherein K=M−1+C, and C is a positive integer.
